(19) United States
(12) Patent Application Publication
(10) Pub. No.: US 2026/0291525 A1
(43) Pub. Date: Sep. 24, 2026

(54) DECODING WITH COMPONENT CODES

(71) Applicants: Massachusetts Institute of Technology, Cambridge, MA (US); National University of Ireland Maynooth, Maynooth (IE); Northeastern University, Boston, MA (US)

(72) Inventors: Muriel Medard, Belmont, MA (US); Peihong Yuan, Cambridge, MA (US); Kenneth R. Duffy, Belmont, MA (US); Kevin Patrick Galligan, Mullingar (IE)

(73) Assignees: Massachusetts Institute of Technology, Cambridge, MA (US); National University of Ireland Maynooth, Maynooth (IE); Northeastern University, Boston, MA (US)

(21) Appl. No.: 19/040,177

(22) Filed: Jan. 29, 2025

Related U.S. Application Data
(60) Provisional application No. 63/626,166, filed on Jan. 29, 2024.

(51) Int. Cl. H03M 13/45; H03M 13/03

(52) U.S. Cl. CPC H03M 13/45; H03M 13/03

(57) ABSTRACT

Described herein are systems, devices, and techniques that use soft-input (SI) guessing random additive noise decoding (GRAND) to provide soft-output (SO) in the form of an accurate a-posteriori estimate of the likelihood that a decoding is correct, or in the case of list decoding, the likelihood that each element of the list is correct. Also described is how to apply disclosed systems, devices, and techniques in the case where GRAND is used for decoding the component codes when the overall code is a product code or related construction, such as a generalized low-density parity-check (GLDPC). Further described is how to apply disclosed systems, devices, and techniques in the case where Polar-like decoding is used for component codes, including a framework that exploits the tradeoff between the undetected error rate (UER) and block error rate (BLER) of Polar-like codes.

### CROSS-REFERENCE TO RELATED APPLICATIONS

This application claims the benefit under 35 U.S.C. § 119 of U.S. Provisional Patent Application No. 63/626,166 filed on Jan. 29, 2024, which is hereby incorporated by reference herein in its entirety.

### STATEMENT REGARDING FEDERALLY SPONSORED RESEARCH

This invention was made with government support under HR0011-21-2-0008 awarded by the Defense Advanced Research Projects Agency. The government has certain rights in the invention.

### BACKGROUND

Multiple error-correction schemes make use of component codes. A common principle behind the design of long, high-redundancy codes is to create them by concatenating and composing shorter component codes. Since Shannon's pioneering work, the quest to design efficiently decodable long, high-redundancy codes has resulted in several advances, including product codes, concatenated codes, turbo codes, turbo product codes, and low-density parity-check (LDPC) codes. Since their rediscovery in the 1990s and the subsequent development of practical encoders and decoders, LDPC codes have become a standard for high performance, long, large redundancy, soft-input (SI) error correction codes. They are used, for example, in standards including Advanced Television Systems Committee (ATSC) 3.0 and 5G New Radio. Such codes include product codes, LDPC codes and variants such generalized low-density check (GLDPC) codes.

Guessing random additive noise decoding (GRAND) is a recently developed family of code-agnostic decoding algorithms that can accurately decode any moderate redundancy code in both hard detection and soft detection settings. GRAND algorithms function by sequentially inverting putative noise effects, ordered from most to least likely according to channel properties and soft information, from received signals. The first codeword yielded by inversion of a noise effect is a maximum-likelihood decoding.

### SUMMARY

The complexity of product encoding compares favorably with that of LDPCs. The naive application of Gaussian elimination schemes leads to cubic complexity. Variants on the theme of product codes, such as staircase codes and GLDPC codes, were developed specifically to overcome the poor minimum distance of the original design.

As discussed herein, decoding a GLDPC code with soft-output guessing random additive noise decoding (SOGRAND) can result in significantly steeper error rate curves and better performance than LDPC codes (e.g., codes used in the 5G standard) at higher signal-to-noise ratio (SNR). To overcome the complexity of LDPC encoding, one or more constraints can be imposed. These constraints include LDPCs with convolutional codes, spatially coupled LDPCs, using the sparsity of LDPCs for lower triangulation in the encoding matrix, restricting the Tanner graphs to exhibit a more product-code-like structure, column-scaled LDPCs, dual-diagonal structures, increasing field sizes, root-protographs structures and, primarily, quasi-cyclic low-density parity-check (QC-LDPC) codes. Indeed, one of the main reasons for the widespread use of quasi-cyclic (QC) codes is to reduce complexity.

With soft-input (SI), each component is decoded and provides soft output (SO) that informs the decoding of another component. The process is repeated, passing updated soft information around the code structure until a global consensus is found or the effort is abandoned. Core to decoding performance is a combination of code-structure, which determines how soft information is circulated amongst components, and the quality of the SO of the decoder, which captures how much is gleaned from each decoding of a component code. For example, turbo decoding of Elias's product codes can avail of powerful component codes, such as Bose-Chaudhuri-Hocquenghem (BCH) codes, but relies on approximate SO, while LDPC codes avail of weak single parity check codes but can provide perfect per-component SO.

Described herein are concepts, structures, and techniques that use SI guessing random additive noise decoding (GRAND) to provide SO in the form of an accurate a-posteriori estimate of the likelihood that a decoding is correct, or in the case of list decoding, the likelihood that each element of the list is correct.

According to a first aspect of the present disclosure, a general technique can be used to generate a reliability measure for a component code to aid in decoding of the overall code. Techniques are described for using reliability information of the accuracy of a decoding, SO, specifically for a component decoder and utilizing that SO for further decoding of the overall code. In other cases, such as multiple-input multiple-output (MIMO) systems, SO can be used for iterative decoding over multiple antennas. In some fading channels, bit-interleaved coded modulation (BICM) causes performance loss due to bit-metric decoding (BMD), i.e., the bit levels are treated independently at the receiver. BICM with iterative decoding (BICM-ID) compensates for the BICM loss by sending the bitwise SO from the decoder back to the demapper. The general technique uses novel SO for iterative decoding. Central to this is the development of a method through which any Soft GRAND (SGRAND) algorithm can provide SO in the form of an accurate a-posteriori estimate of the likelihood that a decoding is correct or, in the case of list decoding, the likelihood that each element of the list is correct.

As used herein, the terms “data unit” and “unit of data” refer to any unit of data capable of being demodulator and/or decoded, including but not limited to a bit, symbol, or block of data.

As used herein, “soft input” or “SI” generally refers to extra information, received by a decoder, that is indicative of the reliability of each unit of input data to be decoded (e.g., the reliability of each bit/symbol/block of demodulated channel output). As used herein, “soft output” or “SO” generally refers to extra information, provided by a decoder, indicative of the confidence (or “belief”) in the decoding of each unit of decoded output data. SI and SO can be per-block, per-symbol, or per-bit, for example.

According to a second aspect of the present disclosure, the general technique can be applied in the case where GRAND is used for decoding the component codes when the overall code is a product code or related construction, such as a GLDPC. A distinguishing feature of SOGRAND in comparison to other methods is the provision of an estimate that the correct decoding has not been found, even when providing a single decoding. That per-block SO can be converted into accurate per-bit SO by a weighted sum that includes a term for the SI. Implementing SOGRAND adds negligible computation and memory to the existing decoding process, and using it results in a practical alternative to LDPC codes.

As discussed herein, a large and flexible class of long, high redundancy error correcting codes can be efficiently and accurately decoded with guessing random additive noise decoding (GRAND). Performance evaluation demonstrates that it is possible to construct simple concatenated codes that outperform low-density parity-check (LDPC) codes found in the 5G New Radio standard. The concatenated structure enables many desirable features, including: low-complexity hardware-friendly encoding and decoding; high levels of flexibility in length and rate through modularity; and high levels of parallelism in encoding and decoding that enable low latency.

Disclosed concepts, structures, and techniques extend GRAND's range of operation by establishing that SO variants can be used to accurately and efficiently decode long, high-redundancy codes. In general, an SI GRAND algorithm can itself readily produce more accurate SO along with its decoding, thus providing improved block error rate (BLER) and bit error rate (BER) performance as well as lower complexity.

Further described is how to apply disclosed structures and techniques in the case where polar-like decoding is used for component codes, including a framework that exploits the tradeoff between the undetected error rate (UER) and BLER of polar-like codes. The presented framework exploits the tradeoff between the UER and BLER of polar-like codes. It relies on a novel approximation referred to as codebook probability, which assumes an auxiliary distribution mimicking the dynamics of decoding algorithms with successive cancellation (SC) decoding schedule. Simulation results demonstrate that, in the case of SC list (SCL) decoding, the disclosed framework outperforms the state-of-art approximations of Forney's generalized decoding rule for polar-like codes with dynamic frozen bits. In addition, the generalized decoding described herein outperforms the cyclic redundancy check (CRC)-concatenated polar codes significantly in both BLER and UER. Potential applications of the approximated codebook probability are disclosed, including coded pilot-free channel estimation and bitwise SO decoding.

According to one aspect of the present disclosure, a method includes: receiving, via a noisy data channel, a plurality of data units encoded with a plurality of component codes of an overall code; receiving soft input (SI) indicative of reliability of individual ones of the plurality of received data units; and for each of the plurality of component codes: decoding, using at least a portion of the SI, one or more of the data units to generate a list of codewords using a decoder for the component code; generating soft output (SO) corresponding to a-posteriori estimate of a likelihood that the decoding is correct; and providing the SO as the SI to a subsequent iteration of the decoding for the same component code or a different one of the plurality of component codes, wherein, for at least one of the plurality of component codes, the generated SO is based, at least in part, on a likelihood that a correct codeword is not included within the list of codewords generated using the decoder for the component code.

According to another aspect of the present disclosure, a forward error-correction decoder comprises one or more processors configured to execute said method.

In some embodiments, for at least one of the plurality of component codes, the decoder includes: a soft-output successive cancellation list (SO-SCL) decoder; a soft-output Guessing Codeword Decoding (SO-GCD) decoder; or a Ordered-Statistics Decoding (SO-OSD) decoder. In some embodiments, for at least one of the plurality of component codes, the decoding includes using a guessing random additive noise decoding (GRAND) algorithm to generate the SO. In some embodiments, the overall code includes: a product code; a generalized low-density check (GLDPC) code; or a concatenation of Polar codes. In some embodiments, the plurality of component codes includes at least two different component codes.

In some embodiments, the plurality of data units comprises a matrix of data units, wherein one or more of the plurality of component codes are associated with one or more respective rows of the matrix, and wherein one or more of the plurality of component codes are associated with one or more respective columns of the matrix. In some embodiments, the SO generated by at least one of the one or more of the plurality of component codes associated with one or more respective rows of the matrix is provided as the SI to at least one of the one or more of the plurality of component codes associated with one or more respective columns of the matrix. In some embodiments, the matrix has three or more dimensions.

In some embodiments, the plurality of data units comprises a matrix of data units, wherein one or more of the plurality of component codes are associated with one or more respective rows of the matrix, and wherein one or more of the plurality of component codes are associated with one or more respective diagonals of the matrix. In some embodiments, the SO generated by at least one of the one or more of the plurality of component codes associated with one or more respective rows of the matrix is provided as the SI to at least one of the one or more of the plurality of component codes associated with one or more respective diagonals of the matrix. In some embodiments, the matrix has three or more dimensions.

In some embodiments, the generating of the SO for at least one of the plurality of component code takes into account a codebook structure for the component code. In some embodiments, the codebook structure is an even code.

It should be appreciated that individual elements of different embodiments described herein may be combined to form other embodiments not specifically set forth above. Various elements, which are described in the context of a single embodiment, may also be provided separately or in any suitable sub-combination. It should also be appreciated that other embodiments not specifically described herein are also within the scope of the following claims.

### BRIEF DESCRIPTION OF THE DRAWINGS

The manner of making and using the disclosed subject matter may be appreciated by reference to the detailed description in connection with the drawings, in which like reference numerals identify like elements.

FIG. 1 is schematic diagram of an illustrative system in which the general concepts, structures, and techniques described herein may be practiced.

FIG. 2 is a graphical diagram showing predicted list-BLER based on SO vs. empirical list-BLER.

FIG. 3 is a schematic diagram of a soft-input soft-output (SISO) decoder, according to some embodiments.

FIG. 3A is a schematic diagram of an illustrative decoder architecture that may be used for SO and updates for component codes, according to some embodiments.

FIG. 4 is a graphical diagram showing predicted BER from soft output vs. empirical BER.

FIG. 5 is a graphical diagram showing BLER and BER performance of a 5G LDPC as compared to a Dynamic Reed Muller (dRM) product code decoded two ways.

FIG. 6 is a graphical diagram showing decoding performance of a 5G LDPC as compared to an eBCH product code decoded with SOGRAND.

FIG. 7 is a graphical diagram showing decoding performance of a 5G LDPC as compared to a CRC 2b9 product code decoded using SOGRAND.

FIG. 8 is a graphical diagram showing decoding performance of a 5G LDPC as compared to another eBCH product code decoded using SOGRAND.

FIG. 9 is a graphical diagram showing decoding performance of a 5G LDPC as compared to a GLDPC code with eBCH nodes.

FIG. 10A illustrates a technique for generating SO with SC decoding of a polar code, according to some embodiments.

FIG. 10B illustrates a technique for extracting SO from GRAND algorithms, according to some embodiments.

FIG. 10C illustrates a technique for generating SO during execution of Guessing Codeword Decoding (GCD), according to some embodiments.

FIG. 11 is a graphical diagram showing predicted BLER vs. simulated BLER of polar-like codes with a disclosed technique and Forney's approximation.

FIGS. 12 and 13 are graphical diagrams showing BLER, UER, miss-detection rate (MDR) vs. E_{b}/N₀ over a binary-input additive white Gaussian noise (biAWGN) channel for dynamic Reed Muller (RM) codes compared to static 5G polar codes.

FIG. 14 is a graphical diagram showing predicted LER vs. simulated LER of polar-like codes under SCL decoding according to a disclosed technique.

FIG. 15 is a graphical diagram showing a random sample of extrinsic information of a static RM code.

FIG. 16 is a graphical diagram showing BER of a static RM code under approximated a-posteriori probability (APP) decoders and Bahl-Cocke-Jelinek-Raviv (BCJR) decoder.

FIG. 17 is a schematic diagram of an illustrative processing system upon which various structures and/or processes disclosed herein may be implemented and/or executed.

FIG. 18A is a schematic diagram illustrating decoding of product codes using SO, according to some embodiments.

FIG. 18B is a schematic diagram illustrating decoding of GLDPC codes using SO, according to some embodiments.

FIG. 18C is a schematic diagram of a cubic tensor code that can be decoded using the general concepts and techniques disclosed herein, according to some embodiments.

The drawings are not necessarily to scale, or inclusive of all elements of a system, emphasis instead generally being placed upon illustrating the concepts, structures, and techniques sought to be protected herein.

### DETAILED DESCRIPTION

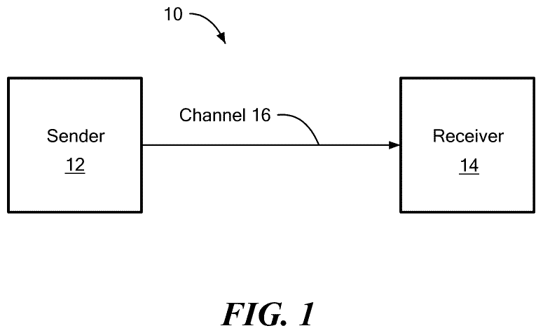

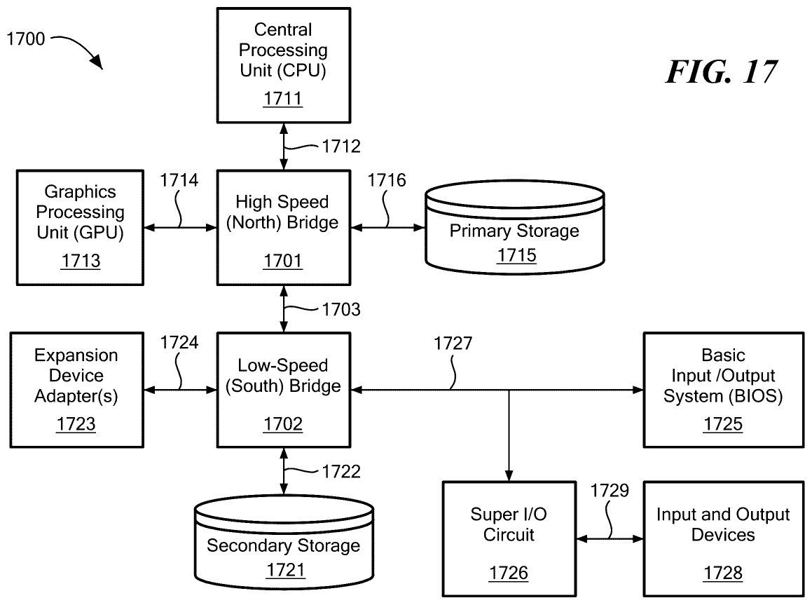

Referring now to FIG. 1, an illustrative, simplified environment in which the general concepts, structures, and techniques described herein may be practiced includes a system 10 for communicating data packets between a sender 12 and a receiver 14 using a data channel 16. Sender 12 may be any device capable of communicating data packets to another device, using the data channel 16. Similarly, receiver 14 may be any device capable of receiving data packets from another device using the data channel 16. Data channel 16 may be any channel known in the art for communicating data packets, including analog and digital channels, and combinations of such channels including the Internet. More generally, data channel 16 can be a medium or plurality of coupled media for communicating data blocks between one or more data senders and one or more data receivers. Sender 12 and receiver 14 each may have, for example, a structure which is the same as or like processing system 1700 shown in FIG. 17.

In operation, data sender 12 sends data toward the data receiver 14 using data channel 16. Data receiver 14 can determine whether received data is valid. If data receiver 14 receives invalid data, then it may assume that noise in data channel 16 has corrupted the data sent by data sender 12, and data receiver 14 must correct for the noise. Embodiments of the concepts described herein include systems, devices, and techniques for correcting for noise are described below in conjunction with the remaining figures.

### Per-Block SO and Updates for Component Codes

As previously discussed, GRAND is a recently developed family of code-agnostic decoding algorithms that can accurately decode any moderate redundancy code in both hard detection and soft detection settings by sequentially inverting putative noise effects. Since this procedure does not depend on codebook structure, GRAND can decode any moderate redundancy code, even non-linear ones. Efficient hardware implementations and syntheses for both hard and soft-detection settings have established the flexibility and energy efficiency of GRAND decoding strategies.

As used herein, the term “codebook” means a set of blocks, or a description of such a set of blocks, shared between the data sender and the data receiver. The term “codeword” means a block in the codebook.

The SO measure developed and disclosed herein is an accurate estimate of the APP that a decoding is correct or incorrect in the case of a single decoding, and, in the case of list decoding, the probability that each codeword in the list is correct or the correct codeword is not in the list. These probabilities are derived for uniform at random codebooks and demonstrate empirically that the resulting formulae continue to provide accurate SO for structured codebooks.

For any channel coding scheme, it would be desirable if error correction decoders could produce SO in the form of a confidence measure in the correctness of a decoded block (e.g., a decoded sequence of symbols). In seminal work on error exponents, Forney proposed an approximate computation of the correctness probability of a decoded block. Forney's approach necessitates the use of a list decoder. Notably, is it not truly a SO but rather the estimate is of the form of a conditional likelihood of correctness given the codeword is in the list. It is demonstrated herein that the approach provides an inaccurate estimate in channels with challenging noise conditions. Regardless, its potential utility motivated further investigation.

With the recent introduction of CRC-Assisted Polar (CA-Polar) codes to communications standards, Forney's approximation has received renewed interest as one popular method of decoding CA-Polar codes, CRC-aided successive cancelation list (CA-SCL) decoding, generates a list of candidate codewords as part of its execution. For convolution or trellis codes, the Viterbi algorithm can be modified to produce SO at the sequence level, which has been used in coding schemes with multiple layers of decoding and to inform repeat transmission requests.

SOGRAND can be readily used with any moderate redundancy code and is not conditioned on the codeword being in a list. Importantly, unlike Forney-style approaches, it includes a term for the likelihood that the correct decoding has not yet been found. As a result, it can be evaluated without the need to list decode and the estimate remains accurate in noisy channel conditions. From it, accurate per-bit SO can be created through a weighted mixture of identified decodings and, with the likelihood that the decoding is not an element of the list, SI. The formulae can be used with any algorithm in the GRAND family so long as SI is available, regardless of the GRAND algorithm's query order. Calculating the SO only requires knowledge of the code's dimensions and the evaluation of the probability of each noise effect query during GRAND's normal operation, so computation of the measure does not significantly increase the decoder's algorithmic complexity or memory requirements. In practical terms, the approach provides accurate SO for single- or list-decoding of any moderate redundancy code of any length and almost any structure.

Following Forney's seminal work, the classical per-block SO, which requires list decoding, is the following approximation: it is the conditional probability that an element of the list is the decoding given the decoding is in the list. The core distinction of SOGRAND is that it foregoes the conditioning by naturally including an estimate of the likelihood that the correct decoding has not been found. Its use significantly improves the quality of the information that circulates after decoding a component code and, in contrast to LDPC codes, allows the practical use of powerful component codes with multiple bits of redundancy.

Notation used in the rest of the disclosure is now defined. Let [symbol] be a codebook containing 2^{k} binary codewords each of length n bits. Let Xⁿ:Ω→ [symbol] be a codeword drawn uniformly at random from the codebook and let Nⁿ:Ω→{0,1}ⁿ denote the binary noise effect that the channel has on that codeword during transmission; that is, Nⁿ encodes the binary difference between the demodulated received sequence and the transmitted codeword, rather than the potentially continuous channel noise. Then Yⁿ=Xⁿ⊕Nⁿ is the demodulated channel output, with ⊕ being the element-wise binary addition operator. Let Rⁿ: Ω→ [symbol] ⁿ denote soft channel output per-bit. Lowercase letters represent realizations of random variables, with the exception of zⁿ, which is the realization of Nⁿ, which is assumed independent of the channel input but could be correlated.

As used herein, “channel input” means a codeword sent by a data sender into a channel. “Channel output” means a corresponding block received by a data receiver from the channel.

All GRAND algorithms operate by progressing through a series of noise effect guesses z^{n,1}, z^{n,2}, . . . ∈{0,1}ⁿ, whose order is informed by channel statistics until it finds one, z^{n,q}, that satisfies

$${\hat{x}}_{q}^{n} = {y}^{n} ⊖ {z}^{n , q} ∈ 𝒞 ,$$

where ⊖ inverts the effect of the noise on the channel output. If the guesses are in channel-dependent decreasing order of likelihood, then z^{n,q} is a maximum-likelihood estimate of Nⁿ and

$${\hat{x}}_{q}^{n}$$

is a maximum-likelihood estimate of the transmitted codeword Xⁿ. Since this guessing procedure does not depend on codebook structure, GRAND can decode any moderate redundancy code as long as it has a method for checking codebook membership. For a linear block code with an (n−k)×n parity-check matrix H,

$${\hat{x}}_{q}^{n}$$

is a codeword if

$$H {\hat{x}}_{q}^{n} = {0}^{n} ,$$

where

$${\hat{x}}_{q}^{n}$$

is taken to be a column vector and 0ⁿ is the zero vector. To generate a decoding list [symbol] of size L, its guessing procedure continues until L codewords are found.

While GRAND algorithms can decode any block code, so-called even linear block codes offer a complexity advantage at no cost in decoding performance so long as the GRAND query generator can skip patterns of a certain Hamming weight. A binary linear code with generator matrix G={G_{i,j}} is even if, with addition in [symbol] ₂,

$${\sum }_{j = 1}^{n} {G}_{i , j}$$

all i∈{1, . . . , K} as if cⁿ∈ [symbol] , then

$${\sum }_{i = 1}^{n} {c}_{i} = 0 .$$

conseqwuently, if a codeword, cⁿ, is perturbed by a channel, yⁿ=cⁿ+Nⁿ, where zⁿ∈{0,1}ⁿ, then with addition in [symbol] ₂,

$${\sum }_{i = 1}^{n} {y}_{i} = {\sum }_{i = 1}^{n} ( {c}_{i} + {z}_{i} ) = \begin{matrix}\underbrace{{\sum }_{i = 1}^{n} {c}_{i}} \\ = 0\end{matrix} + {\sum }_{i = 1}^{n} {z}_{i} = {\sum }_{i = 1}^{n} {z}_{i}$$

and the parity of the demodulated bits yⁿ is the same as the parity of the noise-effect zⁿ that has impacted the codeword cⁿ.

Thus, if an even code is decoded with a GRAND algorithm that has a mechanism to generate putative noise-effect sequences of given Hamming weight only noise effect sequences whose parity is the same as

$${\sum }_{i = 1}^{n} {y}_{i}$$

need be generated. On average, the use of this property with even codes reduces the query number complexity by a factor of up to 2, but the performance is the same as if sequences of any Hamming weight were generated; it is merely that those sequences of mismatched Hamming weight cannot lead to the identification of a codebook element. For the soft detection ORBGRAND algorithms implemented with the Landslide algorithm, it is trivial to skip given Hamming weights and so this approach is employed here whenever even codes are used. Note that ORBGRAND, despite its simplicity, approaches capacity. The Landslide algorithm is described in K. R. Duffy, W. An and M. Médard, “Ordered Reliability Bits Guessing Random Additive Noise Decoding,” in IEEE Transactions on Signal Processing, vol. 70, pp. 4528-4542, 2022, doi: 10.1109/TSP.2022.3203251.

Note that many codes are inherently even. Examples include extended Bose-Chaudhuri-Hocquenghem (eBCH) codes, polar codes and dRM codes. In general, given a generator, G, for a code that is not even, it is straight-forward to extended it by a single column and setting

$${G}_{i , n + 1} = {\sum }_{j = 1}^{n} {G}_{1 , j}$$

in [symbol] ₂, which adds one extra bit to the code and results in an even code. As most codes are good codes, codes that are even also have that property. Additional discussion of even codes is provided below in the section titled (“Soft Output for Even Codes Decoded with Grand”).

Underlying GRAND is a race between two random variables, the number of guesses until the true codeword is identified and the number of guesses until an incorrect codeword is identified. Whichever of these processes finishes first determines whether the decoding identified by GRAND is correct. The guesswork function G:{0,1}ⁿ→{1, . . . , 2ⁿ}, which depends on SI Rⁿ in the soft detection setting, maps a noise effect sequence to its position in GRAND's guessing order, so that G(z^{n,i})=i. Thus G(Nⁿ) is a random variable that encodes the number of guesses until the transmitted codeword would be identified. Note that as Nⁿ is independent of Xⁿ, one has that

$$P ( G ( {N}^{n} ) = q \vert {R}^{n} = {r}^{n} ) = {p}_{{N}^{n} \vert {R}^{n}} ( {z}^{n , q} \vert {r}^{n} ) .$$

Consequently, as Yⁿ=Xⁿ ⊕Nⁿ, for any c″∈

[symbol]

$${p}_{{X}^{n} \vert {R}^{n}} ( {c}^{n} \vert {r}^{n} ) = {p}_{{N}^{n} \vert {R}^{n}} ( {c}^{n} ⊕ {y}^{n} \vert {r}^{n} ) . \qquad ( 1 )$$

If U₍ᵢ₎:Ω→{1, . . . , 2ⁿ−1} is the number of guesses until the i-th incorrect codeword is identified, not accounting for the query that identifies the correct codeword, then GRAND returns a correct decoding whenever G(Nⁿ)≤U₍₁₎ and a list of length L containing the correct codeword whenever G(Nⁿ)≤U_{(L)}. Analysis of the race between these two processes leads to the derivation of the SO in this disclosure.

Forney's work on error exponents resulted in an approximation for SO. Given channel output rⁿ, which serves as SI to the decoder, and a decoding output cⁿ′*∈ [symbol] , the probability that the decoding is correct is

$${p}_{{X}^{n} \vert {R}^{n}} ( {c}^{n , *} \vert {r}^{n} ) = \frac{{f}_{{R}^{n} \vert {X}^{n}} ( {r}^{n} \vert {c}^{n , *} )}{{\sum }_{{c}^{n} ∈ 𝒞} {f}_{{R}^{n} \vert {X}^{n}} ( {r}^{n} \vert {c}^{n} )} . \qquad ( 2 )$$

Based on this formula, Forney derived an optimal threshold for determining whether a decoding should be marked as an erasure. Evaluating the sum in the denominator of eq. (2), would, however, require 2^{k} computations, which is infeasible for codebooks of practical size. As a result, given a decoding list [symbol] ⊆ [symbol] with L>1 codewords, Forney suggested the approximation

$${p}_{{X}^{n} \vert {R}^{n}} ( {c}^{n , *} \vert {r}^{n} ) \approx \frac{{f}_{{R}^{n} \vert {X}^{n}} ( {r}^{n} \vert {c}^{n , *} )}{{\sum }_{{c}^{n} ∈ ℒ} {f}_{{R}^{n} \vert {X}^{n}} ( {r}^{n} \vert {c}^{n} ) + {\underbrace{{\sum }_{{c}^{n} ∈ 𝒞 \backslash ℒ} {f}_{{R}^{n} \vert {X}^{n}} ( {r}^{n} \vert {c}^{n} )}}_{assumed to be o}} , \qquad ( 3 )$$

and so becomes the conditional probability that each element of the list is correct given that the transmitted codeword is in the list. With

$${c}^{n , *} = arg {max}_{{c}^{n} ∈ ℒ} {f}_{{R}^{n} \vert {X}^{n}} ( {r}^{n} \vert {c}^{n} ) ,$$

Forney's approximation results in an estimate of the correctness probability of cⁿ′* that is no smaller than 1/L. For example, if L=2, then the correctness estimate is bounded below by ½. Having the codewords of highest likelihood in the decoding list will clearly give the most accurate approximation as their likelihoods dominate the sum.

A significant source of improvement in the SO that results from the method developed and disclosed here for GRAND is that it naturally provides an accurate, non-zero estimate of final term in the denominator of eq. (3), even with a single decoding, i.e. L=1. As a result, disclosed techniques can generate an estimate that is not conditioned on the codeword having been found. That generates better approximations to the denominator in eq. (2), particularly in noisy channels. This enables an estimate of the likelihood of correctness of a single decoding, i.e. for L=1, which is not possible from Forney's approximation, as well as an estimate of the likelihood that the decoding has not been found (i.e. is not in the list):

$${p}_{{X}^{n} \vert {R}^{n}} ( 𝒞 ∖ ℒ \vert {r}^{n} ) = \frac{{\sum }_{{c}^{n} ∈ 𝒞 \backslash ℒ} {f}_{{R}^{n} \vert {X}^{n}} ( {r}^{n} \vert {c}^{n} )}{{\sum }_{{c}^{n} ∈ 𝒞} {f}_{{R}^{n} \vert {X}^{n}} ( {r}^{n} \vert {c}^{n} )} . \qquad ( 4 )$$

It is this unique feature that enables substantially improved SO.

As noted, one other downside of Forney's approach is that it requires a list of codewords, which most decoders do not provide. For this reason, a method has been proposed to estimate the likelihood of the second-most likely codeword given the first. A variety of alternative schemes have also been suggested for making erasure decisions, a summary of which can be found in.

Throughout this section (“Per-block SO and updates for component codes”), it shall be assumed that the codebook, [symbol] , consists of 2^{k} codewords drawn uniformly at random from {0,1}ⁿ, although the derivation generalises to higher-order symbols. For GRAND algorithms exact expressions are first derived, followed by readily computable approximations, for the probability that the transmitted codeword is each element of a decoding list or is not contained within it. As a corollary, a formula for the probability that a single-codeword GRAND output is correct or incorrect is obtained. Below, it is demonstrated the formulae provide excellent estimates for structured codebooks.

Theorem 1 (A-posteriori likelihoods for list decoding of a uniformly random codebook):

Given the soft information Rⁿ=rⁿ that determines the query order, let G(Nⁿ) be the number of codebook queries until the noise effect sequence Nⁿ is identified. Let W₁, . . . , W₂_{^{k}}₋₁ be selected uniformly at random without replacement from {1, . . . , 2ⁿ−1} and define their rank-ordered version U₍₁₎< . . . <U₍₂_{^{k}}₋₁₎. With the true noise effect not counted, U₍ᵢ₎ corresponds to the location in the guesswork order of the i-th erroneous decoding in a codebook constructed uniformly-at-random. Define the partial vectors

$${U}_{( i )}^{j} = ( {U}_{( i )} , … , {U}_{( j )} )$$

for each i≤j∈{1, . . . , 2^{k}−1}.

Assume that a list of L≥1 codewords are identified by a GRAND decoder at query numbers q₁< . . . <q_{L}. Define the associated partial vectors

$${q}_{i}^{j} = ( {q}_{i} , … , {q}_{j} )$$

for each i≤j∈{1, . . . , 2^{k}−1}, and

$${q}_{1}^{L , \{ i \}} = ( {q}_{1} , … , {q}_{i - 1} , {q}_{i + 1} - 1 , … , {q}_{L} - 1 ) , \qquad ( 5 )$$

which is the vector

$${q}_{1}^{L}$$

but with the entry qᵢ omitted and one subtracted for all entries from qᵢ₊₁ onwards.

### Define

$$P ( A ) = {\sum }_{q > {q}_{L}} {p}_{{N}^{n} \vert {R}^{n}} ( {z}^{n , q} \vert {r}^{n} ) {p}_{{U}_{( 1 )}^{L}} ( {q}_{1}^{L} )$$

which is associated with the transmitted codeword not being in the list, and, for each i∈{1, . . . , L−1},

$$P ( {B}_{i} ) = {p}_{{N}^{n} \vert {R}^{n}} ( {z}^{n , {q}_{i}} \vert {r}^{n} ) {p}_{{U}_{( 1 )}^{L - 1}} ( {q}_{1}^{L , \{ i \}} ) ,$$

which is associated with the transmitted codeword being the i-th element of the list, and

$$P ( {B}_{L} ) = {p}_{{N}^{n} \vert {R}^{n}} ( {z}^{n , {q}_{L}} \vert {r}^{n} ) {\sum }_{q \geq {q}_{L}} {p}_{{U}_{( 1 )}^{L - 1} , {U}_{( L )}} ( {q}_{1}^{L - 1} , q ) ,$$

which is associated with the transmitted codeword being the final element of the list. Then the probability that i-th codeword is correct is

$$\frac{P ( {B}_{i} )}{P ( A ) + {\sum }_{i = 1}^{L} P ( {B}_{i} )} . \qquad ( 6 )$$

and the probability that the correct decoding is not in the list is

$$\frac{P ( A )}{P ( A ) + {\sum }_{i = 1}^{L} P ( {B}_{i} )} . \qquad ( 7 )$$

### Proof of Theorem 1:

For q∈{1, . . . , 2ⁿ}, define U_{(i),q}=U₍ᵢ₎+1_{{U(i)≥q}}, so that any U₍ᵢ₎ that is greater than or equal to q is incremented by one. Note that U_{(i),G(N}_{ⁿ}₎ encodes the locations of erroneous codewords in the guesswork order of a randomly constructed codebook given the value of G(Nⁿ) and, in particular, U_{(i),G(N}_{ⁿ}₎ corresponds the number of queries until the i-th incorrect codeword is found given G(Nⁿ).

Given the soft information Rⁿ=rⁿ that determines the query order, one can identify the event that the decoding is not in the list as

$$A = \{ G ( {N}^{n} ) > {q}_{L} , {U}_{( 1 )}^{L} = {q}_{1}^{L} \}$$

and the events where the decoding is the i-th element of the list by

$${B}_{i} = \{ {U}_{( 1 )}^{i - 1} = {q}_{1}^{i - 1} , G ( {N}^{n} ) = {q}_{i} , {U}_{( i )}^{L - 1} + 1 = {q}_{i + 1}^{L} , {U}_{( L )} \geq {q}_{L} \}$$

where the final condition is automatically met for i={1, . . . , L−1} but not for i=L. The conditional probability that a GRAND decoding is not one of the elements in the list given that L elements have been found is

$$P ( A \vert A {⋃}_{i = 1}^{L} {B}_{i} , {R}^{n} = {r}^{n} ) = P ( A \vert {R}^{n} = {r}^{n} ) / P ( A {⋃}_{i = 1}^{L} {B}_{i} \vert {R}^{n} = {r}^{n} ) . \qquad ( 8 )$$

As all of the A and Bᵢ events are disjoint, to compute eq. (8) it suffices to simplify P(A) and P(Bᵢ) for i∈{1, . . . , L} to evaluate the a-posteriori likelihood that the transmitted codeword is not in the list.

Consider the numerator,

$$P ( A ) = P ( G ( {N}^{n} ) > {q}_{L} , {U}_{( 1 )}^{L} = {q}_{1}^{L} \vert {R}^{n} = {r}^{n} ) = {\sum }_{q > {q}_{L}} {p}_{{N}^{n} \vert {R}^{n}} ( {z}^{n , q} \vert {r}^{n} ) {p}_{{U}_{( 1 )}^{L}} ( {q}_{1}^{L} ) ,$$

where the fact that G(Nⁿ) is independent of

$${U}_{( 1 )}^{L}$$

by construction is used. In considering the denominator, one need only be concerned with the terms P(Bᵢ) corresponding to a correct codebook being identified at query qᵢ, for which

$$P ( {B}_{i} ) = P ( G ( {N}^{n} ) = {q}_{i} , {U}_{( 1 )}^{i - 1} = {q}_{1}^{i - 1} ,$$

$${U}_{( i )}^{L - 1} + 1 = {q}_{i + 1}^{L} , {U}_{( L )} \geq {q}_{L} \vert {R}^{n} = {r}^{n} ) = P ( G ( {N}^{n} ) = {q}_{i} , {U}_{( 1 )}^{L - 1} = {q}_{1}^{L , \{ i \}} ,$$

$${U}_{( L )} \geq {q}_{L} \vert {R}^{n} = {r}^{n} ) = {p}_{{N}^{n} \vert {R}^{n}} ( {z}^{n , {q}_{i}} \vert {r}^{n} ) {\sum }_{q \geq {q}_{L}} {p}_{{U}_{( 1 )}^{L - 1} , {U}_{( L )}} ( {q}_{1}^{L , \{ i \}} , {q}_{k} ) ,$$

where the definition of

$${q}_{1}^{L , \{ i \}}$$

in eq. (3) and the independence is used. Thus the conditional probability that the correct answer is not found in eq. (8) is given in eq. (7) and the conditional probability that a given element of the list is correct is given by eq. (6).

Specializing to a list size L=1, the formula in eq. (7) for the a-posteriori likelihood that decoding is incorrect can be expressed succinctly, as in the following corollary.

Corollary 1 (A-posteriori likelihood of a correct GRAND decoding for a uniformly random codebook):

The conditional probability that a GRAND decoding is correct given the first codeword is identified on the q-th query is

$$\frac{{p}_{{N}^{n} \vert {R}^{n}} ( {z}^{n , q} \vert {r}^{n} ) {\sum }_{j \geq q} {p}_{{U}_{( 1 )}} ( j )}{{p}_{{N}^{n} \vert {R}^{n}} ( {z}^{n , q} \vert {r}^{n} ) {\sum }_{j \geq q} {p}_{{U}_{( 1 )}} ( j ) + {\sum }_{j > q} {p}_{{N}^{n} \vert {R}^{n}} ( {z}^{n , j} \vert {r}^{n} ) {p}_{{U}_{( 1 )}} ( q )}$$

where U₍₁₎ is equal in distribution to the minimum of 2^{k}−1 numbers selected uniformly at random without replacement from {1, . . . , 2ⁿ−1}.

As a result of Theorem 1 and its corollary, in order to compute the APP of an incorrect decoding in Theorem 1, one can evaluate or approximate:

$$\begin{matrix}1 ) & \\ {p}_{{N}^{n} \vert {R}^{n}} ( {z}^{n , q} \vert {r}^{n} ) and {\sum }_{j \leq q} {p}_{{N}^{n} \vert {R}^{n}} ( {z}^{n , j} \vert {r}^{n} ) ; & \end{matrix}$$

$$\begin{matrix}2 ) & \\ {p}_{{U}_{( 1 )}^{L}} ( {q}_{1}^{L} ) and {\sum }_{k \geq L} {p}_{{U}_{( 1 )}^{L - 1} , {U}_{( L )}} ( {q}_{1}^{L - 1} , {q}_{k} ) . & \end{matrix}$$

In some embodiments, during a GRAND algorithm's execution, the evaluation of 1) can be achieved by calculating the likelihood of each noise effect query as it is made and retaining a running sum. For 2), geometric approximations whose asymptotic precision can be verified using known approaches, resulting in the following corollaries for list decoding and single-codeword decoding, respectively. Note that these estimates only need to know the code dimensions, n and k, rather than any specifics of the code construction.

Corollary 2 (Approximate a-posteriori likelihood of an incorrect GRAND list decoding for a uniformly random codebook):

If each U₍ᵢ₎ given U₍ᵢ₋₁₎ is assumed to be geometrically distributed with probability of success (2^{k}−1)/(2ⁿ−1), eq. (7) describing the APP that list decoding does not contain the transmitted codeword can be approximated as

$$\frac{( 1 - {\sum }_{j = 1}^{{q}_{L}} {p}_{{N}^{n} \vert {R}^{n}} ( {z}^{n , j} \vert {r}^{n} ) ) ( \frac{{2}^{k} - 1}{{2}^{n} - 1} )}{{\sum }_{i = 1}^{L} {p}_{{N}^{n} \vert {R}^{n}} ( {z}^{n , {q}_{i}} \vert {r}^{n} ) + ( 1 - {\sum }_{j = 1}^{{q}_{L}} {p}_{{N}^{n} \vert {R}^{n}} ( {z}^{n , j} \vert {r}^{n} ) ) ( \frac{{2}^{k} - 1}{{2}^{n} - 1} )} \qquad ( 9 )$$

### Proof of Corollary 2:

Define the geometric distribution's probability of success to be φ=(2^{k}−1)/(2ⁿ−1). Under the assumptions of the corollary, one has the formulae

$${p}_{{U}_{( 1 )}^{L}} ( {q}_{1}^{L} ) = {( 1 - ϕ )}^{{q}_{L} - L} {ϕ}^{L} ,$$

for i∈{1, . . . , L−1}

$${p}_{{U}_{( 1 )}^{L - 1}} ( {q}_{1}^{L , \{ i \}} ) = {( 1 - ϕ )}^{{q}_{L} - L} {ϕ}^{L - 1} , \qquad ( 1 )$$

$$and$$

$$P ( {U}_{( 1 )}^{L - 1} = {q}_{1}^{L - 1} , {U}_{( L )} \geq {q}_{L} ) = {( 1 - ϕ )}^{{q}_{L} - L} {ϕ}^{L - 1} .$$

Using those expressions, simplifying eq. (7) gives eq. (9).

To a slightly higher precision, and according to some embodiments, the following approximation can be used, which accounts for eliminated queries and is most succinctly expressed for a single-codeword decoding.

Corollary 3 (Approximate a-posteriori likelihood of an incorrect GRAND decoding for a uniformly random codebook):

If U₍₁₎ is assumed to be geometrically distributed with probability of success (2^{k}−1)/(2ⁿ−q) after q−1 failed queries, eq. (7) describing the APP that a decoding found after q₁ queries is incorrect can be approximated as

$$\frac{( 1 - {\sum }_{j = 1}^{{q}_{1}} {p}_{{N}^{n} \vert {R}^{n}} ( {z}^{n , j} \vert {r}^{n} ) ) \frac{{2}^{k} - 1}{{2}^{n} - {q}_{1}}}{{p}_{{N}^{n} \vert {R}^{n}} ( {z}^{n , {q}_{1}} \vert {r}^{n} ) + ( 1 - {\sum }_{j = 1}^{{q}_{1}} {p}_{{N}^{n} \vert {R}^{n}} ( {z}^{n , j} \vert {r}^{n} ) ) \frac{{2}^{k} - 1}{{2}^{n} - {q}_{1}}} . \qquad ( 10 )$$

### Proof of Corollary 3:

Under the conditions of the corollary,

$$P ( {U}_{( 1 )} = {q}_{1} ) = {\prod }_{i = 1}^{{q}_{1} - 1} ( 1 - \frac{{2}^{k} - 1}{{2}^{n} - i} ) \frac{{2}^{k} - 1}{{2}^{n} - {q}_{1}} ,$$

from which eq. (7) simplifies to eq. (10).

In some embodiments, these theorems and corollaries can be used together to provide a simple accounting methodology from which GRAND can provide a-posterior distribution on the correctness of each element of a decoding list, including the possibility of a list of size L=1, as well as the likelihood that the correct decoding has not been found. In particular, it suffices to:
1. know the code-dimensions, (n, k);
2. record the likelihood of each noise-effect sequence that leads to a decoding, P_{N}_{ⁿ}_{|R}_{ⁿ}(z^{n,q}^{ᵢ}|rⁿ) for i∈{1, . . . , L} for a list of size L; and
3. record the cumulative probability of all queries made until that final element was found,

$${\sum }_{j = I}^{{q}_{L}} {p}_{{N}^{n} \vert {R}^{n}} ( {z}^{n , j} \vert {r}^{n} ) .$$

Using these, the APP per decoding block, and the log-likelihood ratio per bit can be computed, according to some embodiments.

With the approximate a-posteriori probabilities in eqs. (9) and (10), their precision for random and structured codebooks can be investigated.

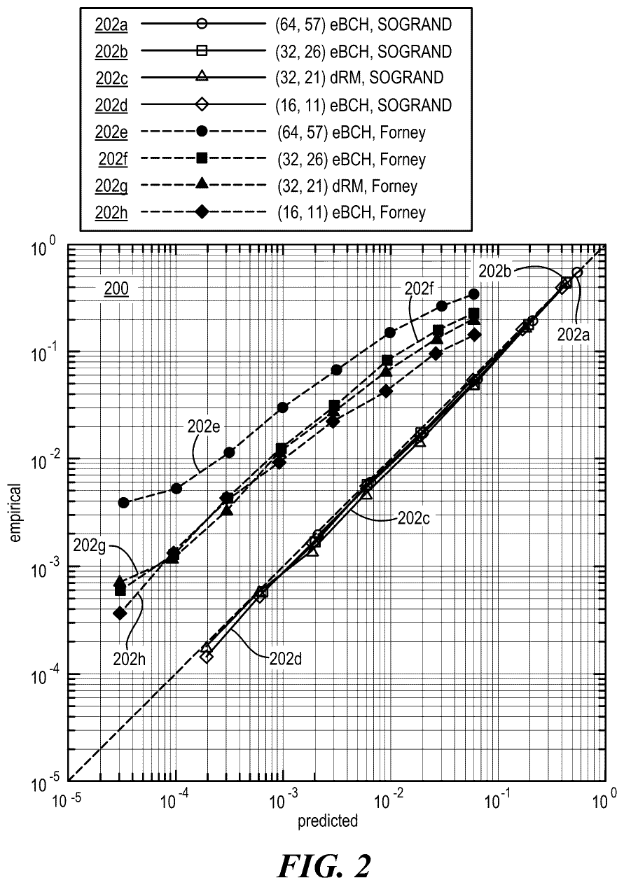

FIG. 2 is a graph 200 showing predicted list-BLER based on SO (horizontal axis) vs. empirical list-BLER (L′=4) (vertical axis). Eight plots 202a-h are shown, with four plots 202a-d representing SOGRAND with L=4 and four plots 202e-h representing Forney with L=5, E_{b}/N₀=2.

FIG. 2 depicts the accuracy of eq. (10). In the figure, transmissions are simulated using an additive white Gaussian noise (AWGN) channel with binary phase-shift keying (BPSK) modulation. Also in the figure, ORBGRAND is used for SI decoding, which produces decoding lists of the appropriate size for both SO methods.

Graph 200 includes plots 202a-h of the empirical list-BLER given the predicted list-BLER evaluated using the approximation of eq. (10). A list error occurs when the transmitted codeword is not in the list of size L′. If the estimate was precise, then the plot would follow the line x=y, as the predicted list-BLER and the list-BLER would match.

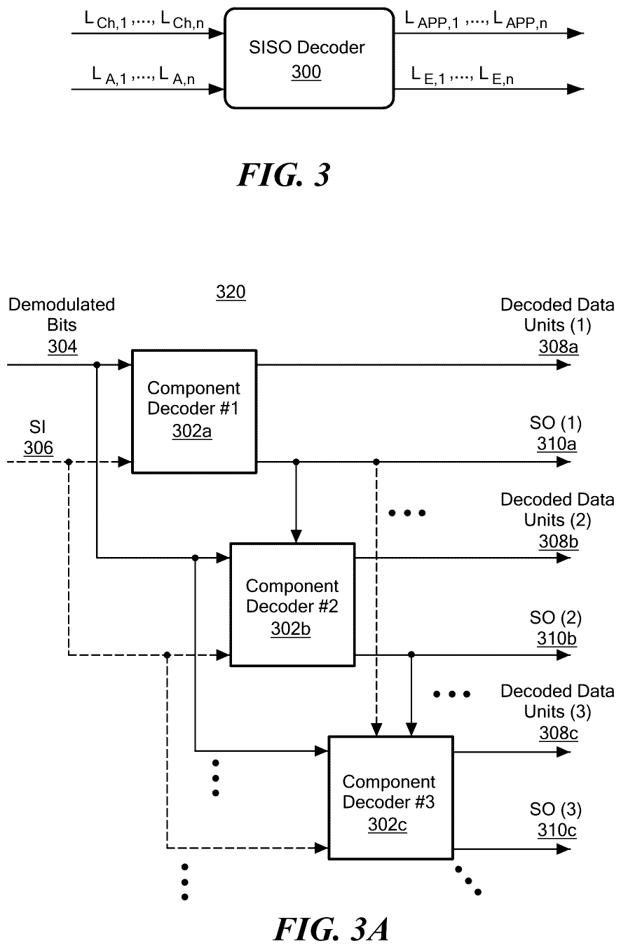

Turning to FIG. 3, for many applications, and according to some embodiments, a system requires post-decoding bitwise SO. A SISO decoder 300 is shown with its inputs and outputs. SISO decoder 300 can take the sum of channel log-likelihood ratio (LLR) L_{Ch,i} and a-priori LLR L_{A,i} as input, where

$${L}_{C h , i} = log \frac{{p}_{R \vert X} ( {r}_{i} \vert 0 )}{{p}_{R \vert X} ( {r}_{i} \vert 1 )} , {L}_{A , i} = log \frac{p {x}_{i} ( 0 )}{{p}_{{X}_{i}} ( 1 )} , i = 1 , … , n .$$

and returns (i.e., output) APP LLR L_{APP,i} and extrinsic LLR L_{E,i} as output, where

$${L}_{APP , i} = log \frac{{p}_{{X}_{i} \vert {R}^{n}} ( 0 \vert {r}^{n} )}{{p}_{{X}_{i} \vert {R}^{n}} ( 1 \vert {r}^{n} )} ,$$

$${L}_{E , i} = {L}_{APP , i} - {L}_{A , i} - {L}_{C h , i} , i = 1 , … , n .$$

Based on the list-BLER prediction from eq. (10), the bitwise SO APP LLRs L_{APP,i} can be approximated by

$${L}_{APP , i}^{′} = log \frac{{\sum }_{{c}^{n} ∈ ℒ : {c}_{i} = 0} {p}_{{X}^{n} \vert {R}^{n}} ( {c}^{n} \vert {r}^{n} ) + {p}_{{X}^{n} \vert {R}^{n}} ( 𝒞 \backslash ℒ \vert {r}^{n} ) {p}_{X \vert {R}_{i}} ( 0 \vert {r}_{i} )}{{\sum }_{{c}^{n} ∈ ℒ : {c}_{i} = 1} {p}_{{X}^{n} \vert {R}^{n}} ( {c}^{n} \vert {r}^{n} ) + {p}_{{X}^{n} \vert {R}^{n}} ( 𝒞 \backslash ℒ \vert {r}^{n} ) {p}_{X \vert {R}_{i}} ( 1 \vert {r}_{i} )} \qquad ( 11 )$$

which reflects the content of each codeword in the list as well as its likelihood, in addition to the likelihood that the codeword is not found whereupon the prior information is retained.

FIG. 3A illustrates a generalized decoder architecture 320 that may be used for SO (e.g., per-block SO) and updates for component codes, according to some embodiments. A plurality of component decoders 302a, 302b, 302c, etc. (302 generally) can each receive demodulated bits 304 and (optionally) SI 306 as input, and produce respective demodulated bits 308a, 308b, 308c, etc. and respective SO 310a, 310b, 310c, etc. as output. While FIG. 3A shows data input in the form of demodulated bits 304, other data units such as blocks or symbols may be received as input.

Decoder 320 may be implemented, for example, within a receiver system (e.g., receiver 14 of FIG. 1). Demodulated bits 304 may correspond to data received over a noisy channel from a sender (e.g., over channel 16 from sender 12 of FIG. 1), and demodulated using demodulation hardware and/or software provided within the receiver system. SI 306 may generally correspond to extra information that is indicative of the reliability of each unit of input data to be decoded. In some embodiments, SI 306 may correspond to real-valued channel output information generated by the demodulation hardware/software (in contrast to demodulated bits 304 which may be “hard” zeros or ones, for example). Various known techniques for demodulating real-valued channel output information to provide SI may be utilized.

Decoders 302 can be provided in a cascade arrangement, with SO from one decoder (e.g., SO 310a from decoder 302a) provided as input to a next decoder in the cascade (e.g., decoders 302b). Optionally, SO 310a may be provided as input to subsequent decoders in the cascade arrangement, such as decoder 302c. The SO can be per block, per symbol, and/or per bit. Likewise, the demodulated bits 304 and decoded bits 308a, 308b, 308c, etc. can represent demodulated blocks/symbols/bits and decoded blocks/symbols/bits, respectively.

In some embodiments, different decoders 302 may implement different component codes. In some embodiments, every decoder 302 may implement a different component code. In some embodiments, two or more decoders 302 can implement the same component code.

In some embodiments, decoder architecture 320 may perform multiple iterations of decoding, with the SO from a one iteration being provided as the SI to the next iteration. Within a given iteration, the multiple component decoders 302 can operate in parallel or in series. The iterative process can continue until one or more termination conditions are met. For example, the process can terminate after all codebooks check (e.g., all demodulated symbols are confirmed to exist with a codebook). As another example, the process can terminate after a fixed number of iterations have been performed (i.e., after a fixed amount of work). As another example, the process can terminate based on the quality of the SO (e.g., if probabilities indicated by the SO are less than an acceptable threshold, if the probabilities diverge over multiple iterations, etc.).

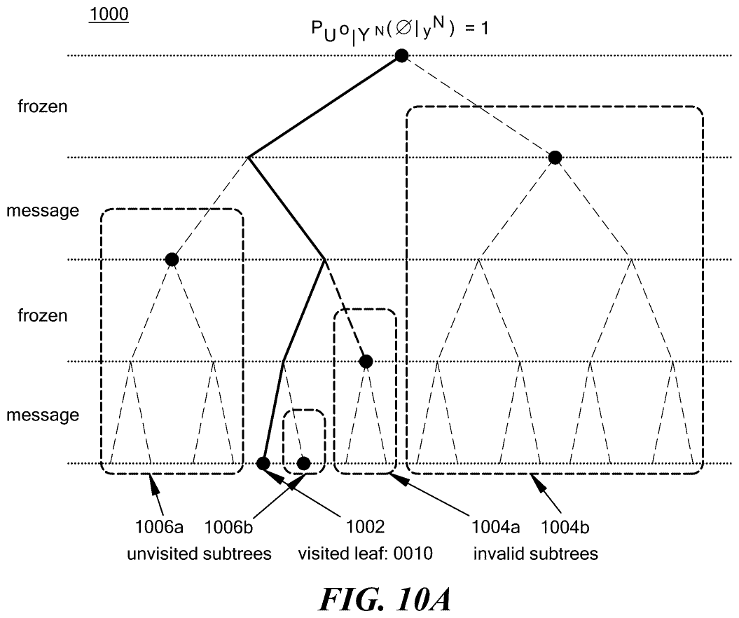

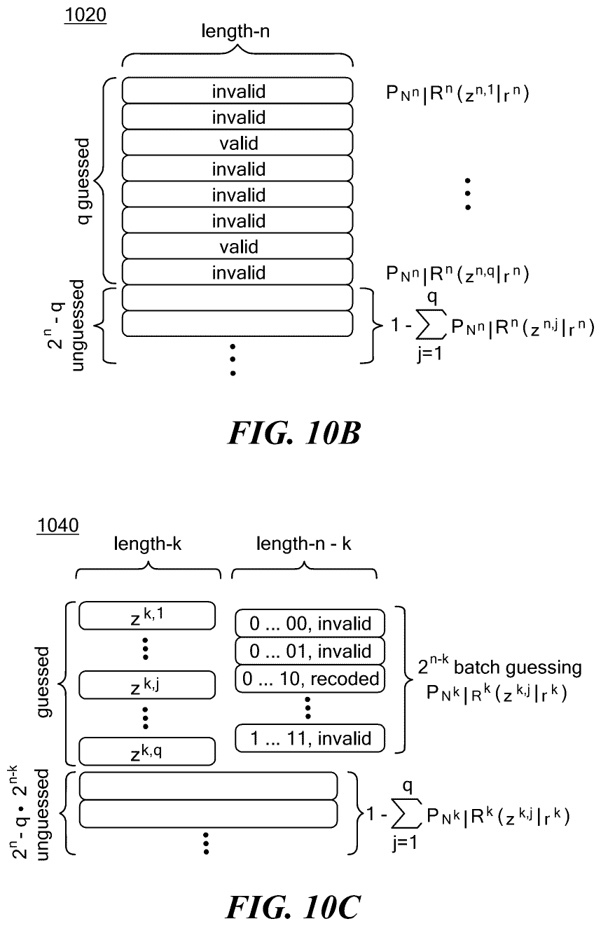

The general architecture of FIG. 3A can be used with various types of codes, component codes, and decoding techniques. For example, decoders 302 can include soft-output successive cancellation (SOSC) decoders, soft-output successive cancellation list (SO-SCL) decoders soft-output Guessing Codeword Decoding (SO-GCD) decoders, soft-output SOGRAND decoders, soft-output Ordered-Statistics Decoding (SO-OSD) decoders, and/or other types of SISO decoders. FIG. 10A illustrates operation of a SOSC decoder. FIG. 10B illustrates operation of a SO-GCD decoder. FIG. 10C illustrates operation of a SOGRAND decoder.

### GRAND Per Block SO

When compared to Pyndiah's approximation,

$$log \frac{{max}_{{c}^{n} ∈ ℒ : {c}_{i} = 0} {p}_{{X}^{n} \vert {R}^{n}} ( {c}^{n} \vert {r}^{n} )}{{max}_{{c}^{n} ∈ ℒ : {c}_{i} = 1} {p}_{{X}^{n} \vert {R}^{n}} ( {c}^{n} \vert {r}^{n} )}$$

eq. (10) introduces an additional term to dynamically adjust the weight between the list observation and channel observation. Furthermore, eq. (10) eliminates the need for the saturation value present in Pyndiah's approximation.

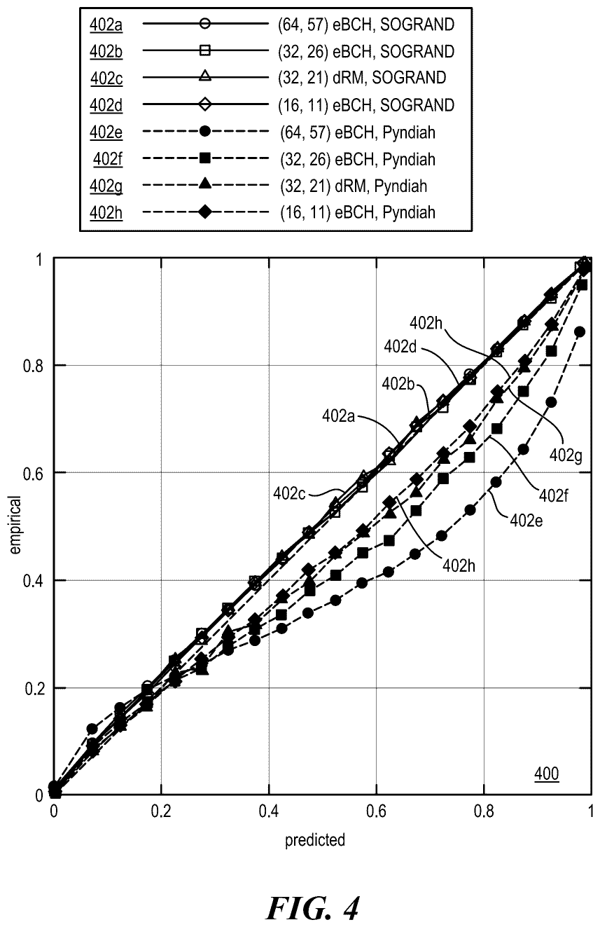

Turning to FIG. 4, a graph 400 shows predicted BER from soft output vs. empirical BER: L=4, E_{b}/N₀=2. FIG. 4 shows the BER prediction obtained from eq. (11) and ORBGRAND decoding. Eight plots 402a-h are shown, with four plots 402a-d corresponding to SOGRAND and four plots 402e-h corresponding to Pyndiah's approximation. The simulated results show that with the disclosed GRAND approach, eq. (11) predicts the BER of the hard decisions of channel outputs accurately across a range of channel conditions, code rates, and code types.

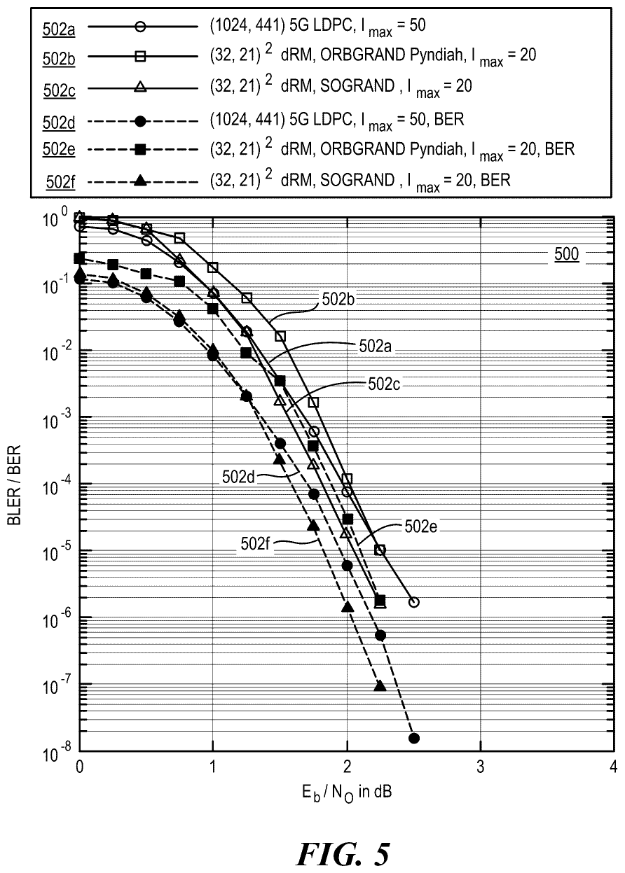

Turning to FIG. 5, a graph 500 shows BLER and BER performance of the (1024,441) 5G LDPC with maximum iteration number Iₘₐₓ=50 as compared to a (1024,441)=(32,21)₂ dRM product code decoded two ways. (As used herein, the notation (<integer 1>, <integer 2>) is shorthand for N=<integer 1> and K=<integer 2>.) Six plots 502a-f are shown. First, turbo-decoded with a and B parameters taken from Pyndiah's original paper and maximum iteration number Iₘₐₓ=20, but using 1 line-ORBGRAND for list decoding with list size L=4. Second, turbo-decoded using a=0.5 and SOGRAND with Iₘₐₓ=20, where lists are added to until L=4 or the predicted list-BLER is below 10⁻⁴.

The merit of SOGRAND is demonstrated in FIG. 5 where BLER vs Eb/N0 in dB for the (1024,441) LDPC in the 5G New Radio standard is plotted. Also shown is the performance of a simple product code, a (1024,441)=(32,21)² dRM code, decoded two distinct ways. Using Pyndiah's original SO methodology but with a list provided by the 1-line version of ORBGRAND, which enhances its performance over traditional Chase decoding, the product code mildly under-performs in comparison with the LDPC code. Even though product codes are known to have poor minimum distance, when decoded with the SOGRAND structures and techniques disclosed here, the new high-quality SO results in the product code seeing a ca. 0.2 dB gain in performance resulting in it outperforming the LDPC code. Consistent with previous findings for GRAND algorithms, it is shown that this improved performance comes with reduced complexity.

A comparison of LDPC codes and product codes of other dimensions is presented, and consistent or better findings are established: when decoded with SOGRAND, Elias's product codes provide as good or better performance as state-of-the-art codes and do so with modest complexity.

Two types of long codes can be constructed based on short components (n, k) codes: (n², k²) product codes and (n², n²−2n (n−k)) QC-GLDPC codes with adjacency matrix

$$[ \begin{matrix}{I}_{n}^{( 0 )} & {I}_{n}^{( 0 )} & … & {I}_{n}^{( 0 )} \\ {I}_{n}^{( 0 )} & {I}_{n}^{( 1 )} & … & {I}_{n}^{( n - 1 )}\end{matrix} ] ,$$

where

$${I}_{n}^{( i )}$$

a n×n circulant permutation matrix obtained by the right rotation (by 1 position) of the identity matrix. Either, or both, of these types of long codes can be used, according to different embodiments of the present disclosure.

Product codes can be thought of as a special case of the QC-GLDPC ensemble with variable node degree-2. According to some embodiments, block turbo decoding of product codes can operate as follows:
The channel LLRs are stored in an n×n matrix L_{Ch}. The a-priori LLRs of the coded bits are initialized to all zero, i.e., L_{A}=0.
Each row of L_{Ch}+L_{A} is processed by a SISO decoder, and the resulting APP LLRs and extrinsic LLRs are stored in the corresponding rows of L_{APP} and L_{E}, respectively. A hard decision is made based on L_{APP}. If all rows and columns of the decision correspond to valid codewords, the block turbo decoder returns the hard output, indicating successful decoding. Otherwise, L_{A} is set to αL_{E} and the decoder proceeds to the column update.
Each column of L_{Ch}+L_{A} is decoded and the columns of L_{APP} and L_{E} are updated as step 1. A hard decision is performed using L_{APP}. If the obtained binary matrix is valid, decoding success is declared. If the maximum iteration count is reached, a decoding failure is returned. Otherwise, set L_{A}=αL_{E} and proceed to the next iteration (i.e., return to step 1).

In simulation, one can set α=0.5 and use 1-line ORBGRAND in conjunction with eq. (11) as the SISO decoder. In some embodiments, and as explained herein, with even codes, the demodulated signal can be used to identify the parity of the noise effect that is being sought, thus reducing complexity.

Decoding of GLDPC codes is based on the belief propagation (BP) principle over the Tanner graph which is a generalization of the block turbo decoding of product codes. Each decoding iteration consists of an exchange of soft messages between variable nodes (VN) and check nodes (CN). Each CN works as a SISO decoder as described below, i.e., each CN treats the extrinsic LLRs from last iteration as a-priori information and generates the corresponding extrinsic LLRs. Again, for SOGRAND 1-line ORBGRAND with eq. (11) can be used. In simulation, the outgoing extrinsic LLRs are always weighted with the scaling factor α=0.5. At the end of each iteration, an APP LLR can be calculated for each coded bit, and a hard decision can be made. If the resulting binary sequence is a valid codeword, then decoding can be declared complete.

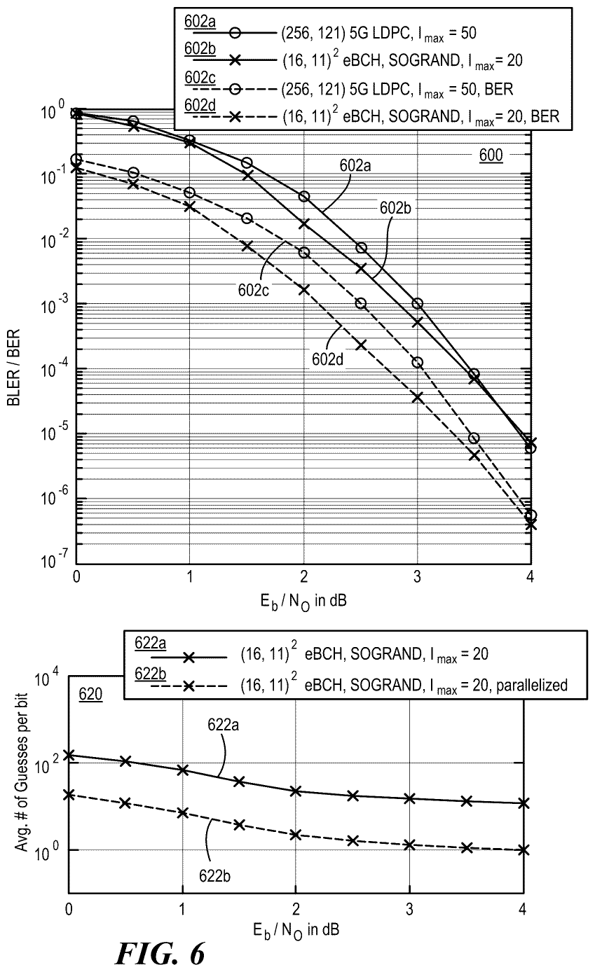

FIG. 6 shows decoding performance of the (256,121) 5G LDPC with maximum number of iterations Iₘₐₓ=50 as compared to a (256,121)=(16,11)² eBCH product code decoded with SOGRAND, i.e. using 1 line-ORBGRAND for SO list decoding with list size L=4, α=0.5 and maximum iteration number Iₘₐₓ=20. In the figure, a first graph 600 shows BLER and BER performance using plots 602a-d, with plots 602a,c corresponding to 5G LDPC and plots 602b,d corresponding to SOGRAND. A second graph 620 shows average number of queries per-bit until a decoding with SOGRAND using plots 622a,b. For plot 622b, labeled “parallelized,” it is assumed that all rows/columns are decoded in parallel.

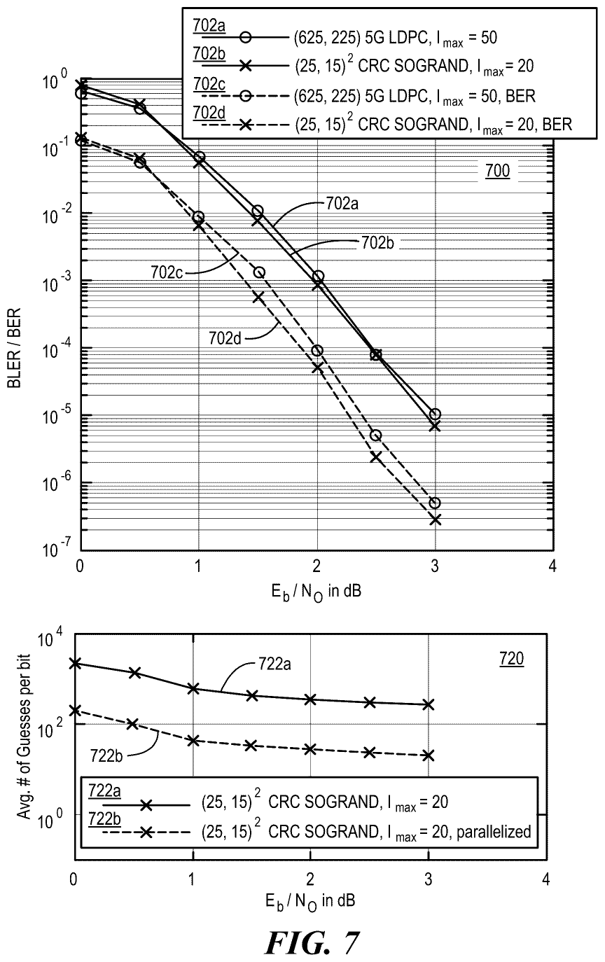

FIG. 7 shows decoding performance of the (625,225) 5G LDPC with maximum number of iterations Iₘₐₓ=50 as compared to a (625,225)=(25,15)² CRC 2b9 product code decoded using SOGRAND with list size L=4, α=0.5 and maximum iteration number Iₘₐₓ=20. In the figure, a first graph 700 shows BLER and BER performance using plots 702a-d, with plots 702a,c corresponding to 5G LDPC and plots 702b,d corresponding to SOGRAND. A second graph 720 shows average number of queries per-bit until a decoding with SOGRAND using plots 722a,b. For plot 722b, labeled “parallelized,” it is assumed that all rows/columns are decoded in parallel.

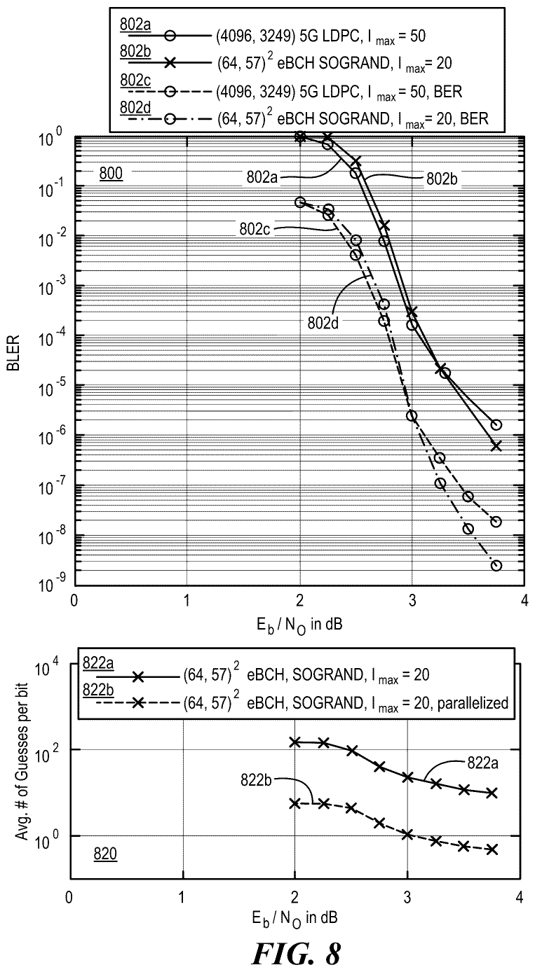

FIG. 8 shows decoding performance of the (4096,3249) 5G LDPC with maximum iterations Iₘₐₓ=50 as compared to a (4096,3249)=(64,57)² eBCH product code decoded using SOGRAND, with α=0.5 and Iₘₐₓ=20, where lists are added to until L=4 or the predicted list-BLER is below 10⁻⁴. In the figure, a first graph 800 shows BLER and BER performance using plots 802a-d, with plots 802a,c corresponding to 5G LDPC and plots 802b,d corresponding to SOGRAND. A second graph 820 shows average number of queries per-bit until a decoding with SOGRAND using plots 822a,b. For plot 822b, labeled “parallelized,” it is assumed that all rows/columns are decoded in parallel.

The results in FIG. 8 show that Elias's original product code, which is known to have poor minimum distance, can give better BLER performance than a 5G LDPC code when decoded with the disclosed SOGRAND. It is first demonstrated that this holds consistently for other code dimensions, where all LDPC codes are from the 5G NR standard.

FIG. 6 shows a comparison for (256,121) LDPC and a (16,11)² eBCH product code, where it can be seen that the product code outperforms the LDPC in terms of both BLER and BER. The lower plot shows the average number of SOGRAND code-book queries per-bit per product code decoding, which serves as a proxy for decoding complexity, latency, and energy consumption, showing reduced effort for improved decoding. Note that each iteration of the 1-line ORBGRAND decoding of a product code all rows or column component codes can be decoded entirely in parallel. In that setting, the parallelized results in FIG. 6 show the average sum of the maximum number of queries per-bit required for each parallel decoding of all rows or columns, which results in significantly reduced decoding latency. Furthermore, GRAND codebook queries are themselves parallelizable, which can be exploited in in-silicon realizations where multiple queries are made per clock-cycle, according to some embodiments.

As GRAND algorithms can decode various types of codes (e.g., any moderate redundancy code), the product code construction is not confined to the dRM and eBCH codes reported in FIGS. 5 and 6. That is, other component codes may be used according to some embodiments.

FIG. 7 provides a further example where a (625,225) LDPC code is compared with a (25,15)² product code that uses a simple CRC code as its component code. Again, the product code outperforms the LDPC code with fewer iterations, minimal complexity, and extremely low latency when parallelized.

FIG. 8 provides a further comparison for the (4096,3249) LDPC code and a (64,57)² eBCH product code, resulting in the same conclusion. Thus, when decoded in an iterative fashion with 1-line ORBGRAND and the SO techniques disclosed herein, Elias's product codes, which predate LDPC codes, offer comparable or better performance than the LDPC codes selected for 5G NR.

While the LDPC codes used in 5G NR trade waterfall (i.e., a plot that generally directed downward) for an error floor (i.e., a plot that levels off at some minimum value), variants of product codes called GLDPC codes have been developed that have better minimum distance and much lower error floors. As with product codes, and according to some embodiments, GLDPC code components can also be decoded in parallel, which would result in low-latency decoding.

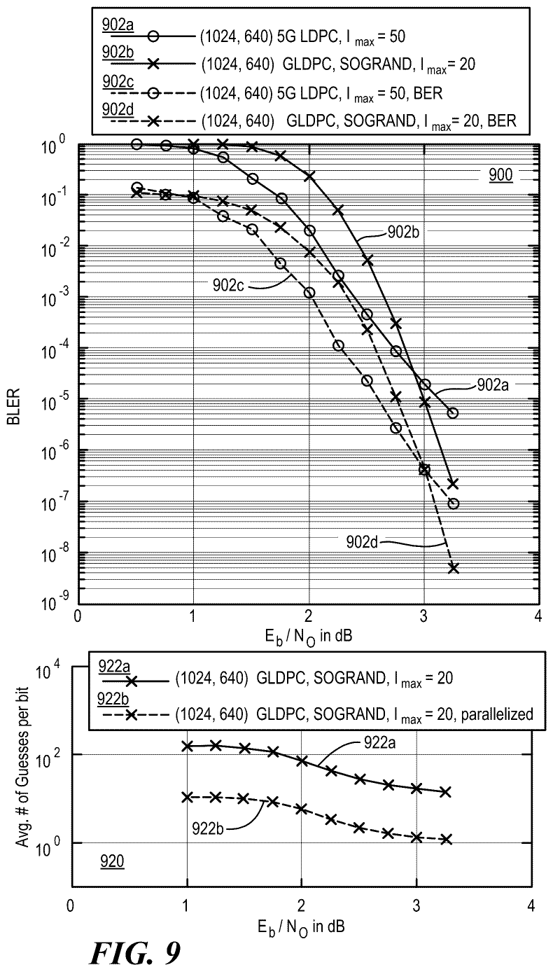

FIG. 9 provides results for one such example when a GLDPC is decoded with SOGRAND. The GLDPC results in a significantly steeper waterfall BLER curve with a significantly lower error floor, at the expense of slightly degraded performance at lower SNR, offering more design possibilities for future systems.

FIG. 9 shows decoding performance of the (1024,640) 5G LDPC with Iₘₐₓ=50 as compared to a (1024,640) GLDPC code with eBCH nodes, 1 line-ORBGRAND with maximum list size Lₘₐₓ=4, where lists are terminated if the predicted list-BLER is below 10⁻⁴, and maximum iteration number Iₘₐₓ=20. In the figure, a first graph 900 shows BLER performance using plots 902a-d, with plots 902a,c corresponding to 5G LDPC and plots 902b,d corresponding to SOGRAND. A second graph 920 shows average number of queries per-bit until a decoding with GRAND using plots 922a,b. For plot 922b, labeled “parallelized,” it is assumed that all rows/columns are decoded in parallel.

Product codes have attractive properties in terms of encoding complexity and latency. To encode each row or column of a systematic code requires only k(n−k) binary operations, where (n−k) is generally small. There are k such rows and n columns, resulting in a total complexity of (k+n)k(n−k), but all k components can be encoded in parallel and then all n components can be encoded in parallel, resulting in a latency of 2k(n−k) which is of order k.

In some embodiments, for component codes of this size, encoding can be performed in hardware in one clock cycle with in-memory computation so, with full parallelism, encoding would take a total of two clock cycles. The QC structure of the GLDPC codes described herein also allows linear complexity encoding as for product codes with similar parallelism for minimal latency.

In contrast, the encoding complexity of LDPC codes can be significant. The naïve application of Gaussian elimination schemes leads to cubic complexity in n. In order to tackle the complexity issues with LDPC encoding, several structures can be imposed on LDPC codes. These constraints include LDPC codes with convolutional codes, spatially coupled LDPC codes, using the sparsity of LDPC codes for lower triangulation in the encoding matrix, restricting the Tanner graphs to exhibit a more product-code-like structure, column-scaled LDPC codes, dual-diagonal structures, increasing field sizes, root-protographs structures and, primarily, QC-LDPCs. Advantageously, no such nuance is required with SOGRAND and according to embodiments of the present disclosure.

Efficient soft-detection decoding of powerful long, low-rate error correction codes has long been a core objective in information theory. A successful approach has been to create long codes by appropriate concatenation of component codes that can provide SO from their SI in an iterative fashion. Turbo codes use powerful component codes but approximate SO while LDPC codes use weak component codes but accurate SO.

According to embodiments of the present disclosure, GRAND can be used to bridge the gap between Turbo decoding of product codes and LDPC codes by decoding powerful component codes and providing accurate SO with no additional computational burden. It has been shown that when decoded with SOGRAND, simple product-like codes that avail of powerful, high-rate component codes can outperform the LDPC codes in the 5G standard. Circuit designs and a realization of ORBGRAND in hardware illustrate that code-book queries can be parallelized, resulting in low latency, low energy ORBGRAND decoding of component codes. The component codes can be decoded in parallel to generate ultra-low-latency long-code implementations. Due to that feature, it is possible to trade-off decoding area versus latency in hardware by determining the number of 1-line ORBGRAND circuits in a chip. Moreover, the product-code-like design is highly modular and can be readily adapted to distinct lengths and rates without resorting to puncturing or significantly changing the architecture of the decoder. Product-like codes also have a significant encoding latency advantage over LDPC codes as all rows and columns (or diagonals) can be encoded in parallel.

While the general concepts, techniques, and structures can be used with product and GLDPC codes, they can also be applied to a much broad palette of more sophisticated and ultimately more powerful, long, low-rate codes, thus providing a practical solution for soft detection decoding, offering a viable alternative to LDPC codes, as well as additional possibilities. One can consider for example codes such as Implicit Partial Product-LDPC Codes, which use LDPC codes for rows and BCH codes for columns.

### Near-Optimal Generalized Decoding of Polar-Like Codes

On the physical layer of communication systems, reliability hinges on the frequency of decoding errors. Undetected errors occur when the decoder produces a codeword different from the transmitted one, and the system remains unaware of this erroneous decision. Such undetected errors can be more harmful than detected errors (usually labeled as erasure). Thus, code and decoder design objectives can encompass not only reducing the BLER but also maintaining a low UER.

Decoding algorithms can be divided into two classes as complete and incomplete decoders. Complete decoders provide estimates, which are always valid codewords. For instance, any maximum-likelihood (ML) decoding algorithm essentially belongs to this group. On the other hand, an incomplete decoder may provide estimates not fulfilling the conditions of being a member of the underlying code. In this case, although it is a decoding error, the receiver is able to detect this error and avoid any malicious behavior or simply ask for a retransmission. For instance, Bahl-Cocke-Jelinek-Raviv (BCJR) or belief propagation (BP) decoding algorithms are famous incomplete decoders since they attempt to make bit-wise decisions on the coded bits.

The conventional practical method to convert a complete decoder into an incomplete one is to employ a CRC outer code, which provides error-detection capability after using a (complete) decoder for the inner code. A penalty paid for such capability is reflected in the code rate to accommodate long enough CRC code, which should be carefully designed to optimize the trade-off between the BLER and UER. An optimal incomplete decoding algorithm can be viewed as implementing ML decoding followed by a post-decoding threshold test. This test determines whether to accept or reject the ML decision. This approach is optimal in the sense that there is no other decoding rule that simultaneously gives a lower BLER and a lower UER. The metric evaluation for this test is efficiently carried out for terminated convolutional codes and can be well approximated for tail-biting convolutional codes via a modification to BCJR algorithm.

CRC-concatenated polar codes refer to the serial concatenation of polar codes with outer CRC codes. Successive cancellation list (SCL) decoding is typically used to decode CRC-concatenated polar codes. Firstly, an SCL decoder creates a candidate list based on the inner polar code. If none of the candidates in the list pass the CRC test, a decoding failure is declared, i.e., an error is detected. Otherwise, the most likely candidate in the list is selected as the final decision, leading to an undetected error if this is not the same as the transmitted message.

### SC and SO

Described next is a generalized decoding approaches for polar-like codes, leveraging a SC-based decoding algorithm and a novel post-decoding threshold test. During the SC-based decoding process, one can approximate a quantity introduced as codebook probability. The results demonstrate the ratio between the probability of the decoder output and the codebook probability closely aligns with the probability of the output decision being correct for polar-like codes with dynamic frozen bits. The decoder output is then tested by comparing the before-mentioned ratio with a threshold. Simulation results show that polar-like codes with dynamic frozen bits using disclosed generalized decoding outperforms CRC-concatenated polar codes in both BLER and UER. Moreover, potential applications of the codebook probability in coded pilot-free channel estimation and bitwise SO decoding are discussed.

In this disclosure, length-N vectors are denoted as x_{N}=(x₁, x₂, . . . , x_{N}), where xᵢ denotes its i-th entry. For completeness, note that x⁰ is void. A random variable is denoted by an uppercase letter, such as X, and its counterpart, e.g., x, is used for a realization. Then, a random vector is expressed as X^{N}=(X₁, X₂, . . . , X_{N}). The probability density function (PDF) of a continuous random variable and the probability mass function (PMF) of a discrete random variable evaluated at x are denoted as p_{X}(x), where the extensions to the vectors is trivial. A binary-input, discrete, memoryless channel (B-DMCI) is characterized by conditional probabilities p_{Y|C}, where the input takes on values in binary alphabet {0,1} and the output set γ is specified by the considered channel model. For natural numbers, [α]={i:i∈ [symbol] , 1≤i≤α} is written.

A binary polar-like code of block length N and dimension K is defined by a set [symbol] ⊆[N] of indices with | [symbol] |=K and a set of linear functions ƒᵢ, i∈ [symbol] , where N is a positive-integer power of 2 and [symbol] ≙[N]\ [symbol] . The K-bit message is mapped onto the subvector [symbol] of the input

$${u}_{1}^{N}$$

to the polar transtorm, where the frozen bits are evaluated as

$${u}_{i} = {f}_{i} ( {u}^{i - 1} ) , ∀ i ∈ ℱ . \qquad ( 12 )$$

Observe that each frozen bit uᵢ is either statically set to zero (since ƒᵢ are linear) or they change according to the input uⁱ⁻¹, which are called dynamic frozen bits. This representation unifies various modifications of polar codes, e.g., CRC-concatenated polar codes, polar subcodes polarization-adjusted convolutional codes and dynamic RM codes. The codeword is then obtained by applying polar transform as c^{N}=u^{N} [symbol] ^{⊗log}^{₂}^{N}, where [symbol] is the binary Hadamard matrix. The codeword c^{N} is transmitted via N independent uses of a B-DMC.

At the receiver side, SC decoding can observe the channel output y^{N} and perform a sequential greedy search to obtain decisions as

$${\hat{u}}_{i} = \{ \begin{matrix}{f}_{i} ( {\hat{u}}^{i - 1} ) , & i ∈ ℱ \\ arg {max}_{u ∈ \{ 0 , 1 \}} {Q}_{{U}_{i} \vert {Y}^{N} {U}^{i - 1}} ( u \vert {y}^{N} {\hat{u}}^{i - 1} ) , & i ∈ 𝒜\end{matrix} \qquad ( 13 )$$

where Q_{U}_{^{N}}_{|Y}_{^{N}} denotes an auxiliary conditional PMF induced by assuming uniform U^{N} over {0,1}^{N}. This implies that Q_{U}_{^{N}}_{Y|}_{^{N}} assumes the frozen bits [symbol] to be also uniformly distributed and independent of the information bits [symbol] . Observe that SC decoding computes Q_{U}_{ᵢ}_{|Y}_{^{N}}_{U}_{^{i−1}} (uᵢ|y^{N}ûⁱ⁻¹) by treating Uᵢ and all upcoming frozen bits, namely uᵢ₊₁, . . . , u_{N}, as uniformly distributed given the channel observation y^{N} and previous decisions ûⁱ⁻¹. In other words, the frozen constraints can be used to determine which decision to make but do not impact the reliability of the decision. Then, a block error can be declared only if [symbol] ~ [symbol] since eq. (12) is already used in decoding via eq. (13).

SC decoding, with a slight modification, has the ability to provide soft information (in the form of a probability) associated to any partial input ûⁱ∈{0,1}, which is also called a decoding path. In particular, for any given decoding path ûⁱ, one can use the Bayes' rule to write

$${Q}_{{U}^{i} \vert {Y}^{N}} ( {\hat{u}}^{i} \vert {y}^{N} ) = {Q}_{{U}^{i - 1} \vert {Y}^{N}} ( {\hat{u}}^{i - 1} \vert {y}^{N} ) {Q}_{{U}_{i} \vert {Y}^{N} {U}^{i - 1}} ( {\hat{u}}_{i} \vert {y}^{N} {\hat{u}}^{i - 1} ) \qquad ( 14 )$$

where the right-most term Q_{U}_{ᵢ}_{|Y}_{^{N}}_{U}_{^{i−1}} (ûᵢ|y^{N}ûⁱ⁻¹) can be computed efficiently by the standard SC decoding and Q_{U}_{⁰}_{Y}_{^{N}}(Ø|y^{N})≙1 by definition. (The term −log Q_{U}_{ⁱ}_{|Y}_{^{N}}(ûⁱ|y^{N}) is call PM for SC-based decoding in LLR domain.) Note that the frozen constraints are used to determine which decision to make at frozen positions behaving as anchors and are irrelevant to the reliability of the decoding path.

Forney introduced a generalized decoding rule, which relies on a threshold test. The decoder output ĉ^{N} is accepted if

$$\frac{{p}_{{Y}^{N} \vert {C}^{N}} ( {y}^{N} \vert {\hat{c}}^{N} )}{{\sum }_{{c}^{N} ∈ 𝒞} {p}_{{Y}^{N} \vert {C}^{N}} ( {y}^{N} \vert {c}^{N} )} \geq \frac{{2}^{NT}}{1 + {2}^{NT}} \qquad ( 15 )$$

where the threshold parameter T≥0 controls the tradeoff between BLER and UER. Otherwise, the decision is rejected and the decoder outputs an error flag, resulting in a detected error. Forney's generalized decoding rule is optimal in the sense of minimizing the UER for a given BLER (and vice versa). Since the denominator of eq. (15) is difficult to compute in general, one may use a suboptimal decoding rule based on list decoding with

$$\frac{{p}_{{Y}^{N} \vert {C}^{N}} ( {y}^{N} \vert {\hat{c}}^{N} )}{{\sum }_{{c}^{N} ∈ 𝒞} {p}_{{Y}^{N} \vert {C}^{N}} ( {y}^{N} \vert {c}^{N} )} \approx \frac{{p}_{{Y}^{N} \vert {C}^{N}} ( {y}^{N} \vert {\hat{c}}^{N} )}{{\sum }_{{c}^{N} ∈ ℒ} {p}_{{Y}^{N} \vert {C}^{N}} ( {y}^{N} \vert {c}^{N} )} . \qquad ( 16 )$$

The approximation is precise when the list decoder exhaustively enumerates the entire codebook.

In the following, decision regions for SC-based decoding rely on a threshold test of function Γ(y^{N}, û^{N}),

$$Γ ( {y}^{N} , {\hat{u}}^{N} ) {=}^{Δ} \frac{{Q}_{{U}^{N} \vert {Y}^{N}} ( {\hat{u}}^{N} \vert {y}^{N} )}{{\sum }_{{u}^{N} ∈ 𝒰} {Q}_{{U}^{N} \vert {Y}^{N}} ( {u}^{N} \vert {y}^{N} )} \qquad ( 17 )$$

where the set [symbol] contains all decoding path u^{N} that satisfies the frozen constraints, i.e.,

$$𝒰 {=}^{Δ} \{ {u}^{N} ∈ {\{ 0 , 1 \}}^{N} : {u}_{i} = {f}_{i} ( {u}^{i - 1} ) , ∀ i ∈ ℱ \} . \qquad ( 18 )$$

As explained herein, the probability of the decoding path u^{N} is irrelevant to the frozen constraints, i.e., Q_{U}_{^{N}}_{|Y}_{^{N}}(u^{N}|y^{N}) is not necessarily equal to 0 even if u^{N} does not fulfill the frozen constraints.

The core problem of generalized decoding is computing the codebook probability, i.e., the sum of probabilities for all valid decoding paths,

$${Q}_{𝒰} ( {y}^{N} ) {=}^{Δ} {\sum }_{{u}^{N} ∈ 𝒰} {Q}_{{U}^{N} \vert {Y}^{N}} ( {u}^{N} \vert {y}^{N} ) . \qquad ( 19 )$$

Next described is a method to approximate the reliability of unvisited codewords based on SC-based decoding of polar and polar-like codes, according to some embodiments.

According to some embodiments, an SC-based decoding algorithm can divide the decoding tree into three parts:
1. Visited leaves denote the valid visited decoding paths of depth N. Note that there may be more than one visited leaf, e.g., a SCL decoder returns L visited leaves;
2. Invalid subtrees stand for the subtrees rooted at the nodes which are not visited during the decoding due to the conflict of frozen constraints; and
3. Unvisited subtrees are the subtrees rooted at the nodes which satisfy the frozen constraints, but are not visited (usually due to the complexity issues).

FIG. 10A shows an example of a SC decoding tree 1000 of a polar code with frozen bits u₁=u₃=0. A SC decoding tree can include three parts: a visited leaf, invalid subtrees, and unvisited subtrees. With illustrative tree 100, a visited leaf 1002 corresponds to SC output û⁴=(0,1,0,0), invalid subtrees 1004a,b include a subtree rooted at û₁=1 and a subtree rooted at û³=(0,1,1), and unvisited subtrees 1006a,b include a subtree rooted at û²=(0,0) and a leaf û⁴=(0,1,0,1). The SC decoding tree 1000 is merely one simplified example. The general techniques described herein can be applied to decoder polar codes of arbitrary size and structure.

Defined now are sets [symbol] , [symbol] and [symbol] containing the visited leaves, the roots of unvisited subtrees, and the roots of invalid subtrees, respectively. For the simplified decoding tree 1000 example of FIG. 10A, one has

$$𝒱 = \{ ( 0 , 1 , 0 , 0 ) \}$$

$$𝒲 = \{ ( 0 , 0 ) , ( 0 , 1 , 0 , 1 ) \}$$

$$𝒥 = \{ ( 1 ) , ( 0 , 1 , 1 ) \}$$

The codebook probability Qᵤ(y^{N}) is then written as

$${\underbrace{{\sum }_{{u}^{N} ∈ 𝒱} {Q}_{{U}^{N} \vert {Y}^{N}} ( {u}^{N} \vert {y}^{N} )}}_{( a ) all visited leaves} + {\overbrace{{\sum }_{{a}^{i} ∈ 𝒲} {\underbrace{{\sum }_{\begin{matrix}{u}^{N} ∈ 𝒰 \\ {u}^{i} = {a}^{i}\end{matrix}} {Q}_{{U}^{N} \vert {Y}^{N}} ( {u}^{N} \vert {y}^{N} )}}_{( c ) all valid leaves underneath node {a}^{i}}}}^{( b ) all unvisited valid leaves} . \qquad ( 20 )$$

The term (c) in eq. (20) describes the sum the of probabilities for all valid decoding paths underneath node aⁱ. It is assumed that the leaves are uniformly distributed underneath the unvisited node aⁱ. One can use the approximation

$$term ( c ) in Eq . ( 20 ) \approx {2}^{- \vert {ℱ}^{( i : N )} \vert} {P}_{{U}^{i} \vert {Y}^{N}} ( {a}^{i} \vert {y}^{N} ) \qquad ( 21 )$$

where [symbol] ^{(i:N)} denotes the set of indices for the frozen bits in the future, i.e.,

$${ℱ}^{( i : N )} = \{ j : j ∈ ℱ , i \leq j \leq N \} . \qquad ( 22 )$$

The codebook probability eq. (19) can then be approximated by

$$\begin{matrix}{Q}_{𝒰}^{*} ( {y}^{N} ) & {=}^{Δ} & {\underbrace{{\sum }_{{u}^{N} ∈ 𝒱} {Q}_{{U}^{N} \vert {Y}^{N}} ( {u}^{N} \vert {y}^{N} )}}_{sum of prob . for all visited leaves} + & ( 23 ) \\ & & {\underbrace{{\sum }_{{a}^{i} ∈ 𝒲} {2}^{- \vert {ℱ}^{( i : N )} \vert} {Q}_{{U}^{i} \vert {Y}^{N}} ( {a}^{i} \vert {y}^{N} )}}_{approx . sum of prob . for all visited leaves} . & ( 24 ) \\ & & & \end{matrix}$$

The disclosed algorithm to compute

$${Q}_{𝒰}^{*} ( {y}^{N} )$$

is compatible with any SC-based decoders. In some embodiments, during SC-based decoding, when the decoder decide not to visit a subtree rooted at the node aⁱ, for i∈ [symbol] , one can accumulate the probability [symbol] Q_{U}_{ⁱ}_{|Y}_{^{N}}(aⁱ|y^{N}) as the approximated sum of probabilities for all valid leaves underneath node aⁱ. (The probability Q_{U}_{ⁱ}_{|Y}_{^{N}}(aⁱ|y^{N}) is computed by the SC-based decoder and does not require extra complexity.)

For SO-SCL, the soft output can be defined as the function Gamma in eq. (17), where the approximation to the denominator, defined in eq. (19), which is the core difficulty, is described in eq (23) and (24). Thus, SO-SCL can be described in terms of eq. (17) using the approximation in eqs. (23) and (24).

### GRAND and SO

Disclosed next are techniques for extracting SO from SI GRAND algorithms, according to some embodiments.

In the context of SI GRAND algorithms, a method can be provided for extracting accurate SO that obviates the need for a decoding list and can, distinctively, provide SO with a single decoding. Central to the approach is an estimate of the term in eq. (3) that is assumed to be 0 in the Forney and Pyndiah approximations. This estimate can be evaluated during GRAND's execution with minimal additional computation.

As previously discussed, GRAND algorithms operate by progressing through a series of noise effect guesses z^{n,1}, z^{n,2}, . . . ∈{0,1}ⁿ, whose order is informed by channel statistics or SI until it finds one or more, z^{n,q}, that satisfy

$${\hat{x}}_{q}^{n} = {y}^{n} ⊖ {z}^{n , q} ∈ 𝒞 ,$$

where ⊖ inverts the effect of the noise on the channel output. If the guesses are in decreasing order of likelihood, then the the l-th such z^{n,q} is the l-th most likely estimate of Nⁿ and

$${\hat{x}}_{q}^{n}$$

is the l-th most likely estimate of the transmitted codeword Cⁿ. In contrast to successive cancellation list decoders, this approach can be described as a “true” list decoder in the sense that, should the query order go from most likely to least likely, the list sequentially contains the most likely codewords.

As the decoding procedure does not depend on codebook structure, GRAND can decode many different codes of many different structures (e.g., any moderate redundancy code of any structure), including non-linear ones, as long as it has a method for checking codebook membership. Underlying GRAND is a race between the number of guesses until the true codeword would be identified and the number of guesses until an incorrect codeword would be identified. Whichever finishes first determines whether the decoding identified by GRAND is correct.

By noting that eq. (2) can be rewritten as

$${p}_{{C}^{n} \vert {R}^{n}} ( {c}^{n , *} \vert {r}^{n} ) = \frac{{p}_{{N}^{n} \vert {R}^{n}} ( {c}^{n , *} ⊕ {y}^{n} \vert {r}^{n} )}{{\sum }_{{c}^{n} ∈ 𝒞} {p}_{{N}^{n} \vert {R}^{n}} ( {c}^{n} ⊕ {y}^{n} \vert {r}^{n} )} \qquad ( 24.1 )$$

and analyzing the race between those two random variables, the following SO for GRAND has been developed. Note that Cⁿ in the above equation corresponds to a codeword, denoted Xⁿ in eqs. (2) and (3) and elsewhere in this document.

For any noise effect query order, regardless of whether it is from most likely to least likely, it can be assumed that each of L codewords are identified at query numbers q₁, q₂, . . . , q_{L}, so that c^{n,i}=yⁿ ⊕z^{n,q}^{ⱼ}, then the likelihood that c^{n,j} is the correct decoding, i.e. eq. (2), can be approximated as

$$\frac{{p}_{{N}^{n} \vert {R}^{n}} ( {z}^{n , {q}_{j}} \vert {r}^{n} )}{{\sum }_{i = 1}^{L} {p}_{{N}^{n} \vert {R}^{n}} ( {z}^{n , {q}_{i}} \vert {r}^{n} ) + ( 1 - {\sum }_{i = 1}^{{q}_{L}} {p}_{{N}^{n} \vert {R}^{n}} ( {z}^{n , i} \vert {r}^{n} ) ) ( \frac{{2}^{k} - 1}{{2}^{n} - 1} )} . \qquad ( 24.2 )$$

The final term in the denominator of eq. (24.2) essentially replaces the term corresponding to the one set to zero in eq. (3). The guesswork likelihood accounting during SOGRAND's operation is illustrated in FIG. 10B.

FIG. 10B shows an illustration of SOGRAND guesswork likelihood accounting 1020. As shown, to evaluate the SO in eq. (24.2) it suffices to record: a running sum of the likelihood of all noise effect queries that have been made; the likelihoods of the noise effect queries that result in codewords being identified; and the code's dimensions, [n, k]. This blockwise SO approximation, and the bitwise version that results, is accurate for codes of any structure and can be used in a variety of powerful applications.

### GCD and SO

Disclosed next are techniques for generating SO during execution of GCD, according to some embodiments.

While GRAND algorithms can decode any code of any structure, including non-linear ones created with length constraints and cryptographic functions, proposals have been made to exploit the structure of binary linear codes to influence the query order and reduce total query numbers. For example, for even linear block codes, which includes eBCH codes, polar codes, and many others, the parity of the noise effect pattern being sought is the same as the parity of the hard demodulated signal. Using a noise effect generator that can skip given Hamming weights, such as the Landslide algorithm, that property can be used to reduce the total query number by a factor of up to two while providing identical decoding performance.

While not originally described in those terms, it is appreciated herein that GCD can be thought of as a way to use the structure of the codebook to make 2^{n-k} noise effect guesses at a time. Not all of the queries will have high likelihood, but one will necessarily result in a codeword and 2^{n-k}−1 of them will not. If a GRAND algorithm does not avail itself of codebook structure to reduce query numbers for a binary linear code, then the maximum likelihood decoding is identified in fewer queries by GCD. When, for example, decoding an even binary linear code with a GRAND variant that avails of that structure that is not necessarily the case.

GCD is readily understood for systematic binary linear codes where the first k bits are information bits, and y^{k} denotes the systematic demodulated bits. Noise effects are sequentially queried from most likely to least likely on the systematic bits, z^{k,1}, z^{k,2}, . . . alone and then extended via the generator matrix, G, to create a codeword (y^{k}⊕z^{k,i}) G=c^{n,i}. No guarantees are made about the likelihoods of the individual c^{n,i}, but, as originally observed in, the sequence of noise effect queries can cease when

$${p}_{{N}^{k} \vert {R}^{k}} ( {z}^{k , i + 1} \vert {r}^{k} ) \leq {max}_{j ∈ \{ 1 , … , i \}} {p}_{{C}^{n} \vert {R}^{n}} ( {c}^{n , j} \vert {r}^{n} ) \qquad ( 24.3 )$$

as p_{N}_{^{k}}_{|R}_{^{k}} (z^{k,i}|r^{k}) is decreasing in i and p_{N}_{^{k}}_{|R}_{^{k}}(z^{k,i}|r^{k})≥p_{c}_{ⁿ}_{|r}_{ⁿ}(c^{n,i}|rⁿ). Thus any further query will result in a less likely codeword than the most likely one that has already been identified. If the code is non-systematic, a single advance operation that identifies a linear transform can suffice to make the process equivalent to the systematic one.

Viewed through a GRAND lens, each noise effect query on k bits can result in 2^{n-k} queries, those corresponding to all 2^{n-k} possible extensions of which only one can result in a codeword. As the SOGRAND formula in eq. (24.2) holds for an arbitrary query order, it applies for GCD's query order.

Noting that p_{N}_{^{k}}_{|r}_{^{k}}(z^{k,i+1}|r^{k}) equals

$${\sum }_{{a}^{n - k} ∈ {\{ 0 , 1 \}}^{n - k}} {p}_{{N}^{n} \vert {R}^{n}} ( ( {z}^{k , i + 1} , {a}^{n - k} ) \vert {r}^{n} ) ,$$

the combined likelihood of all the length n extrapolated noise effect queries made from a noise effect applied to the k bits, z^{k,i+1}, is already evaluated for the left hand side of the termination condition eq. (24.3).

Noting that each query necessarily results in the identification of a codeword, when considering GCD through the lens of GRAND to extract SO, the likelihood that the codeword identified on the j-th query of L queries is correct can be approximated,

$${p}_{{C}^{n} \vert {R}^{n}} ( {c}^{n , j} \vert {r}^{n} ) \approx \frac{{p}_{{N}^{n} \vert {R}^{n}} ( {c}^{n , j} ⊕ {y}^{n} \vert {r}^{n} )}{\begin{matrix}{\sum }_{i = j}^{L} {p}_{{N}^{n} \vert {R}^{n}} ( {c}^{n , j} ⊕ {y}^{n} \vert {r}^{n} ) + \\ ( 1 - {\sum }_{j = 1}^{L} {p}_{{N}^{k} \vert {R}^{k}} ( {z}^{k} \vert {r}^{k} ) ) ( \frac{{2}^{k} - 1}{{2}^{n} - 1} )\end{matrix}} \qquad ( 24.4 )$$

The likelihood that the decoding is not in the list of identified codewords is then what remains,

$${p}_{{C}^{n} \vert {R}^{n}} ( 𝒞 ∖ ℒ \vert {r}^{n} ) = 1 - {\sum }_{i = 1}^{L} {p}_{{C}^{n} \vert {R}^{n}} ( {c}^{n , j} \vert {r}^{n} ) . \qquad ( 24.5 )$$

Contrasting with the guesswork likelihood accounting required for SOGRAND in FIG. 1, guesswork likelihood accounting 1040 of SO-GCD it is illustrated in FIG. 2.

In order to evaluate eqs. (24.4) and (24.5), the same information is required as for eq. (24.2), which is already available to the decoder, specifically: the likelihood of each codeword that is identified; the sum of the likelihoods of all noise effect sequences that have been queried, including those that do not lead to a codeword; and the code's dimensions.

Based on the blockwise SO in eq. (24.4) and eq. (24.5), the bitwise SO LLR for the i-th bit can be calculated as

$$log \frac{{\sum }_{{c}^{n} ∈ ℒ : {c}_{i} = 0} {p}_{{C}^{n} \vert {R}^{n}} ( {c}^{n} \vert {r}^{n} ) + {p}_{{C}^{n} \vert {R}^{n}} ( 𝒞 \backslash ℒ \vert {r}^{n} ) {p}_{{X}_{i} \vert {R}_{i}} ( 0 \vert {r}_{i} )}{{\sum }_{{c}^{n} ∈ ℒ : {c}_{i} = 1} {p}_{{C}^{n} \vert {R}^{n}} ( {c}^{n} \vert {r}^{n} ) + {p}_{{C}^{n} \vert {R}^{n}} ( 𝒞 \backslash ℒ \vert {r}^{n} ) {p}_{{X}_{i} \vert {R}_{i}} ( 1 \vert {r}_{i} )} , \qquad ( 24.6 )$$

which reflects the content of each codeword in the list and its likelihood, in addition to the likelihood that the codeword is not found, whereupon the prior information is retained.

While GCD terminates after finding the most likely decoding, it generates a list in the process. That list, however, need not contain other likely decodings. GCD's termination condition can be altered to stop after the A most likely codewords have been found by modifying eq. (24.3) to correspond to the A-th most likely codeword in the list. The inventors have demonstrated that the blockwise SO in eq. (24.4) is highly accurate for Random Linear Codes (RLCs), and for highly structured eBCH codes once A is larger than 1. The latter may be required for iterative SISO decoding applications.

As with soft-input GRAND (SGRAND), GCD can provide optimally accurate maximum likelihood decoding when noise effect queries are sequentially created from most likely to least likely. Processing using dynamic memory may be required for algorithms for generating those noise effect sequences. In some embodiments, ORBGRAND can be used to produce noise effect sequences in approximately the decreasing order of likelihood without the need for dynamic memory, making it suitable for highly efficient implementation in circuits. To distinguish GCD driven by ORBGRAND's 1-line order, it can be referred to as GCD-ORB.

SI error correction decoders that generate accurate blockwise or bitwise SO provide significant extra functionality. In some embodiments, blockwise SO can be used to accurately trigger automatic repeat queries/requests (ARQs) or flag data for erasure. For example, referring briefly to FIG. 1, receiver 14 can send ARQs to sender 12 based on blockwise SO generated using the techniques described herein. In some embodiments, bitwise SO can be used in SISO decoders to efficiently decode long, high redundancy codes. It has been shown that accurate SO can be efficiently evaluated during a SI GRAND decoding and the methodology can be extended to successive cancellation decoders. By considering GCD as a sophisticated version of GRAND that makes parallelized queries, it is established herein that SO can be produced with it too.

Next presented are numerical results demonstrating the accuracy of the approximation and the performance of joint error correction and detection. One can consider polar-like codes with two types of information sets
RM codes
5G polar codes
   and two types of frozen constraints
static frozen bits: uᵢ=0, i∈ [symbol]
(convolutional) dynamic frozen bits:

$${u}_{i} = {u}_{i - 2} ⊕ {u}_{i - 3} ⊕ {u}_{i - 5} ⊕ {u}_{i - 6} , i ∈ ℱ , i > 6.$$

In some embodiments, the following metric can be used to evaluate the probability of the output decision being the transmitted codeword,

$${Γ}^{*} ( {y}^{N} , {\hat{u}}^{N} {=}^{Δ} \frac{{Q}_{{U}^{N} \vert {Y}^{N}} ( {\hat{u}}^{N} \vert {y}^{N} )}{{Q}_{𝒰}^{*} ( {y}^{N} )} . \qquad ( 25 )$$

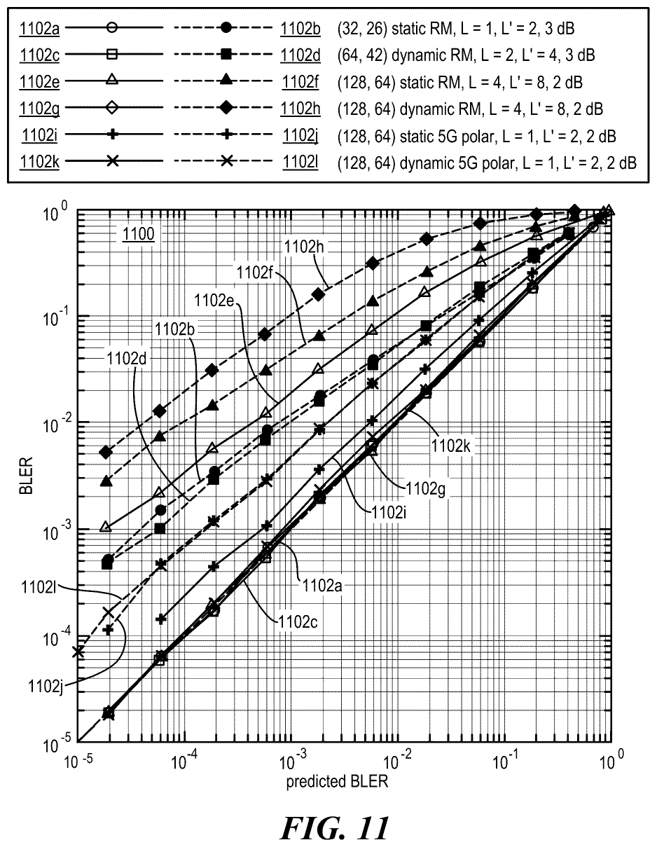

Turning to FIG. 11, a graph 1100 shows predicted BLER vs. simulated BLER of polar-like codes with a disclosed technique and Forney's approximation. As shown, the disclosed technique (plots 1102a,c,e,g,i,k) works with SCL decoding of list size L, while the Forney's approximation (plots 1102b,d,f,h,j,l) works with list size L′.

FIG. 11 plots the BLER given the predicted BLER. Starting a Monte-Carlo (MC) simulation, the codewords are transmitted over biAWGN channels. The SCL decoder outputs a decision û^{N} and block soft output Γ*(y^{N}, û^{N}). One can gather blocks with 1−Γ*(y^{N}, û^{N}) within specific ranges,

$$[ 1 , 1 {0}^{- 0.5} ) , [ 1 {0}^{- 0.5} , {10}^{- 1} ) , … , [ {10}^{- 4.5} , {10}^{- 5} )$$

and compare their BLER to the average predicted BLER E[1−Γ*(y^{N}, û^{N})]. For reference, also shown is the Forney-style approximation with list size | [symbol] |=L′

$${Γ}^{′} ( {y}^{N} , {\hat{u}}^{N} ) = \frac{{Q}_{{U}^{N} \vert {Y}^{N}} ( {\hat{u}}^{N} \vert {y}^{N} )}{{\sum }_{{u}^{N} ∈ ℒ} {Q}_{{U}^{N} \vert {Y}^{N}} ( {u}^{N} \vert {y}^{N} )} \qquad ( 26 )$$

which approximates the codebook probability Qᵤ(y^{N}) as the list probability

$${\sum }_{{u}^{N} ∈ ℒ} {Q}_{{U}^{N} \vert {Y}^{N}} ( {u}^{N} \vert {y}^{N} ) .$$

The results in FIG. 11 show that the approximation accurately predicts the BLER of the polar-like codes with dynamic frozen constraints. The approximation relies on the assumption of uniform leaf distribution under the unvisited node. However, the static frozen bits (after the first message bit) may disrupt this assumption. Thus, the approximation has a mismatch for polar-like codes with static frozen bits. Observe that the approximation yields accurate predictions for static (32,26) RM codes because the count of frozen bits following the first message bit is minimal and insufficient to disrupt the assumption of a uniform leaf distribution. (There are only three frozen bits after the first message bit for the (32,26) static RM code.)

The disclosed approach provides an accurate approximation for codebook probability if polar-like codes with random dynamic frozen bits of any length and rate.

One can apply a threshold test,

$${Γ}^{*} ( {y}^{N} , {\hat{u}}^{N} ) > 1 - ϵ . \qquad ( 27 )$$

The final decision û^{N} can be accepted when eq. (27) is satisfied; otherwise, the decoder can return an error flag. As Γ*(y^{N}, û^{N}) evaluates the probability of the output decision being correct, the decision rule mentioned above imposes an upper limit of ∈ on the MDR, where MDR is defined as the probability of an accepted decision being erroneous, i.e., the ratio between UER and BLER.

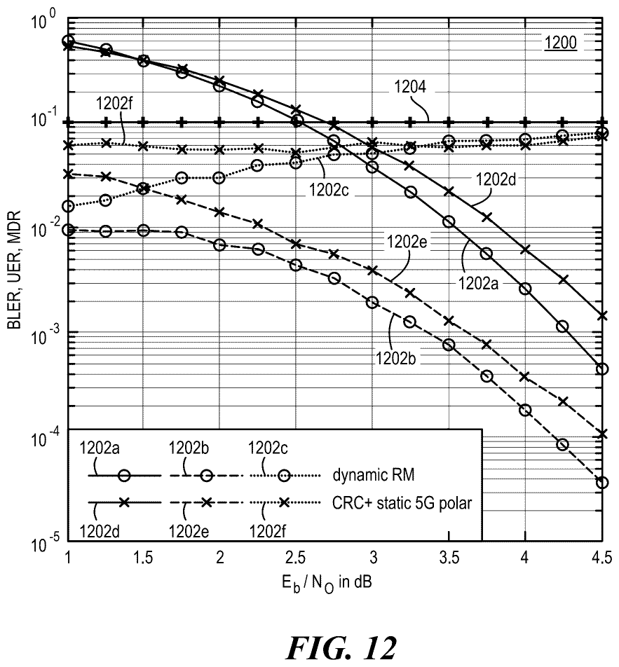

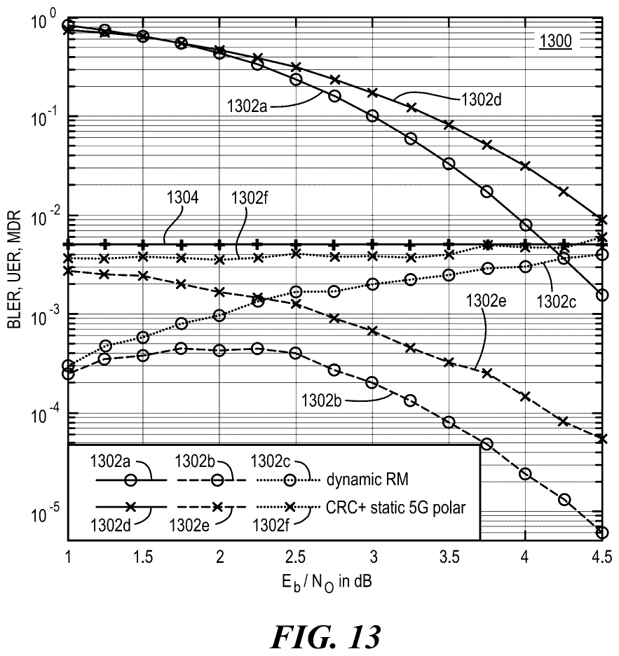

FIGS. 12 and 13 show BLER, UER, MDR vs. E_{b}/N₀ over a biAWGN channel for dynamic RM codes compared to static 5G polar codes.

In FIG. 12, plots 1202a, 1202b, and 1202c correspond respectively to BLER, UER, and MDR vs. E_{b}/N₀ over the biAWGN channel for a (64,42) dynamic RM code. Plots 1202d, 1202e, and 1202f correspond respectively to BLER, UER, and MDR vs. E_{b}/N₀ for a (64,42+6) static 5G polar code with an outer CRC-6 0×30. SCL with L=4, threshold ∈=0.1.

In FIG. 13 plots 1302a, 1302b, and 1302c correspond respectively to BLER, UER, and MDR vs. E_{b}/N₀ over the biAWGN channel for a (64,42) dynamic RM code. Plots 1302d, 1302e, and 1302f correspond respectively to BLER, UER, and MDR vs. E_{b}/N₀ for a (64,42+11) static 5G polar code with an outer CRC-11 0×710. SCL with L=8, threshold ∈=0.005.

FIGS. 12 and 13 show the BLER, UER and MDR of the disclosed decision rule eq. (27) based on the approximation eq. (21) with SCL decoding. For reference, the performance of CRC-concatenated polar codes using SCL with the same list size is demonstrated. If none of the candidates in the list pass the CRC, an error flag is returned. The method is compared with 6-bits CRC using L=4 and 11-bits CRC using L=8. (Note that the MDR of CRC-concatenated polar codes using SCL is influenced by both the CRC size and the list size. The generator polynomial is presented with Koopman's notation.) The threshold ∈ is chosen to achieve a similar MDR to that of CRC-concatenated polar codes. The simulation results show that the disclosed technique outperforms CRC-concatenated polar codes in both BLER and UER. More importantly, the MDR is restricted to not be higher than ∈ (horizontal line 1204 in FIG. 12 and horizontal line 1304 in FIG. 13).

In addition to the primary application discussed in the previous section, the disclosed algorithm has other potential applications. Next described are several areas where the algorithm can provide solutions, according to various embodiments of the present disclosure.

Pilot-free channel estimation based on frozen constraints has been proposed. The channel state information (CSI) h is evaluated via

$$\hat{h} = arg {max}_{h} {Q}_{{U}_{ℱ} \vert {Y}^{N} , H} ( {0}^{N - K} \vert {y}^{N} , h ) \qquad ( 28 )$$

for polar-like codes with static frozen constraints. A related method for estimating CSI utilizes the parity-check constraints of an LDPC code.

Based on the codebook probability given CSI,

$${Q}_{𝒰} ( {y}^{N} , h ) {=}^{Δ} {\sum }_{{u}^{N} ∈ 𝒰} {Q}_{{U}^{N} \vert {Y}^{N} , H} ( {u}^{N} \vert {y}^{N} , h ) , \qquad ( 29 )$$

the CSI is determined by identifying a value that maximizes the codebook probability, i.e.,

$$\hat{h} = arg {max}_{h} {Q}_{𝒰}^{*} ( {y}^{N} , h ) \qquad ( 30 )$$

which is a generalization of eq. (28).

One can evaluate the probability of the candidate list [symbol] contains the transmitted codeword by generalizing eq. (25),

$$Γ * ( {y}^{N} , ℒ ) {=}^{Δ} \frac{{\sum }_{{u}^{N} ∈ ℒ} {Q}_{{U}^{N} \vert {Y}^{N}} ( {u}^{N} \vert {y}^{N} )}{{Q}_{𝒰}^{*} ( {y}^{N} )} . \qquad ( 31 )$$

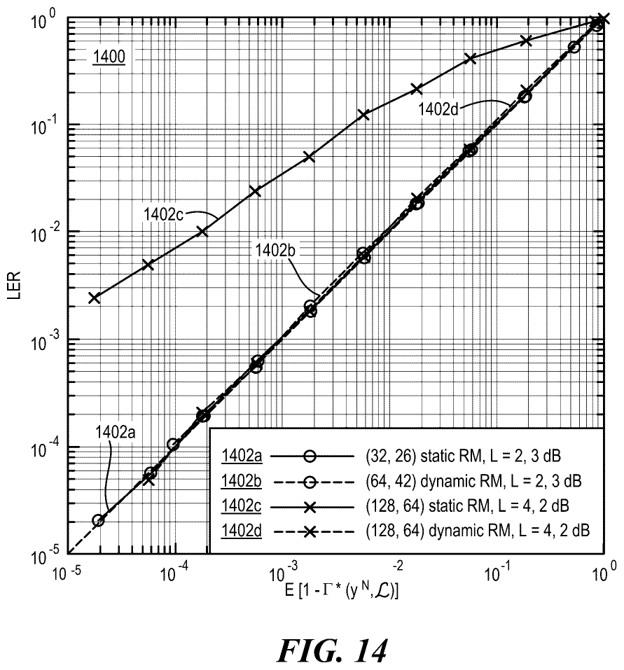

In FIG. 14, a graph 1400 includes plots 1402a-d of the list error rage (LER) given the predicted LER, where the LER is defined as the probability of the transmitted codeword not being in the list. Plots 1402a,c correspond to static RM codes and plots 1402b,d correspond to dynamic RM codes. The results show that Γ*(y^{N}, [symbol] ) accurately predicts the LER of the polar-like codes with dynamic frozen constraints.

In various applications, and according to some embodiments, a system may require post-decoding bitwise soft output. A SISO decoder can take the sum of channel LLR [symbol] , and a-priori LLR, denoted as [symbol] _{A,i}, as input,

$${ℓ}_{i} {=}^{Δ} log \frac{{p}_{Y \vert C} ( {y}_{i} \vert 0 )}{{p}_{Y \vert C} ( {y}_{i} \vert 1 )} , {ℓ}_{A , i} {=}^{Δ} log \frac{{P}_{{C}_{i}} ( 0 )}{{P}_{{C}_{i}} ( 1 )} , i ∈ [ N ] . \qquad ( 32 )$$

It can then output APP LLR, represented as [symbol] _{APP,i}, and extrinsic LLR, represented as [symbol] _{E,i}.

$${ℓ}_{APP , i} {=}^{Δ} log \frac{{P}_{{C}_{i} \vert {Y}^{N}} ( 0 \vert {y}^{N} )}{{P}_{{C}_{i} \vert {Y}^{N}} ( 1 \vert {y}^{N} )} = log \frac{{\sum }_{{c}_{i} = 0 , {c}^{N} ∈ 𝒞} {P}_{{C}^{N} \vert {Y}^{N}} ( {c}^{N} \vert {y}^{N} )}{{\sum }_{{c}_{i} = 1 , {c}^{N} ∈ 𝒞} {P}_{{C}^{N} \vert {Y}^{N}} ( {c}^{N} \vert {y}^{N} )} \qquad ( 33 )$$

$${ℓ}_{E , i} {=}^{Δ} {ℓ}_{APP , i} - {ℓ}_{A , i} - {ℓ}_{i} , i ∈ [ N ] . \qquad ( 34 )$$

For an (N, K) block code, the APP LLR can be determined using the BCJR algorithm with 2^{N-K} states. Pyndiah's approximation extracts [symbol] _{APP,i} and [symbol] _{E,i} from a candidate list [symbol] through list decoding,

$${ℓ}_{APP , i}^{′} = log \frac{{max}_{{}_{{c}_{i} = 0 , {c}^{N} ∈ ℒ}} {P}_{{C}^{N} \vert {Y}^{N}} ( {c}^{N} \vert {y}^{N} )}{{max}_{{}_{{c}_{i} = 1 , {c}^{N} ∈ ℒ}} {P}_{{C}^{N} \vert {Y}^{N}} ( {c}^{N} \vert {y}^{N} )} \qquad ( 35 )$$

$${ℓ}_{E , i}^{′} = \{ \begin{matrix}+ β , if \{ {c}_{i} = 1 , {c}^{N} ∈ ℒ \} = ⌀ \\ - β , if \{ {c}_{i} = 0 , {c}^{N} ∈ ℒ \} = ⌀ \\ {ℓ}_{APP , i}^{′} - {ℓ}_{A , i}^{′} - {ℓ}_{i} , otherwise\end{matrix} . \qquad ( 36 )$$

Note that the saturation value β>0 is sensitive and requires optimization for practical applications.

One can approximate [symbol] _{APP,i} and [symbol] _{E,i} based on Γ*(y^{N}, [symbol] ) via eq. (37). In comparison to Pyndiah's approximation, eq. (37) introduces an additional term to dynamically adjust the weight between list observation and channel observation. Furthermore, eq. (37) eliminates the need for the saturation value present in Pyndiah's approximation.

$${ℓ}_{APP , i} \approx {ℓ}_{APP , i}^{*} ( ℒ ) = log \frac{\begin{matrix}{\sum }_{{c}_{i} = 0 , {c}^{N} ∈ ℒ} {Q}_{{C}^{N} \vert {Y}^{N}} ( {c}^{N} \vert {y}^{N} ) + \\ ( 1 - Γ * ( {y}^{N} , ℒ ) ) \cdot {P}_{C \vert Y} ( 0 \vert {y}_{i} )\end{matrix}}{\begin{matrix}{\sum }_{{c}_{i} = 1 , {c}^{N} ∈ ℒ} {Q}_{{C}^{N} \vert {Y}^{N}} ( {c}^{N} \vert {y}^{N} ) + \\ ( 1 - Γ * ( {y}^{N} , ℒ ) ) \cdot {P}_{C \vert Y} ( 1 \vert {y}_{i} )\end{matrix}} \qquad ( 37 )$$

$${ℓ}_{E , i}^{*} = {ℓ}_{APP , i}^{*} - {ℓ}_{A , i} - {ℓ}_{i} , i ∈ [ N ]$$

$$where$$

$${Q}_{{C}^{N} \vert {Y}^{N}} ( {c}^{N} \vert {y}^{N} ) = {Q}_{{U}^{N} \vert {Y}^{N}} ( {u}^{N} \vert {y}^{N} ) , for {c}^{N} - {u}^{N} {𝔽}^{⊗ {log}_{2} N}$$

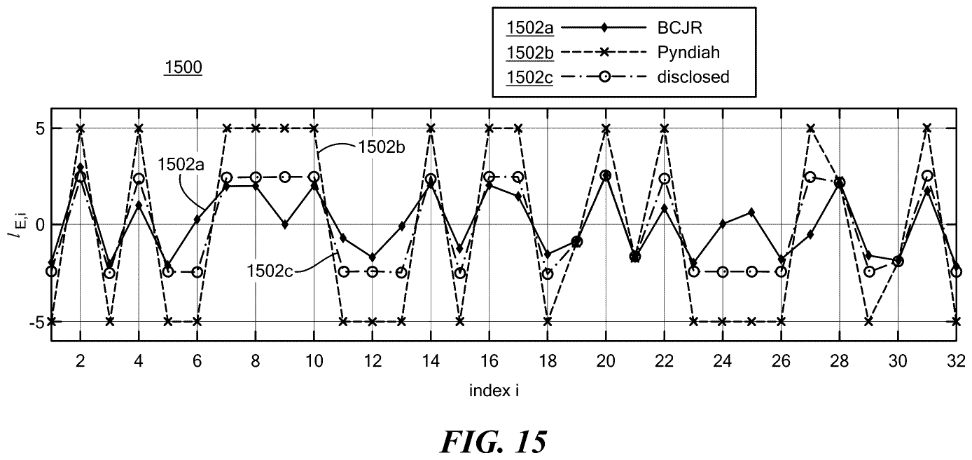

Turning to FIG. 15, a graph 1500 shows a random sample of the extrinsic information of a (32,26) static RM code, L=2 at E_{b}/N₀=2 dB. In this example, the a-priori LLRs are set to 0. The saturation value for Pyndiah's approximation is set to β=5.

FIG. 15 displays a random sample of the extrinsic LLRs [symbol] _{E,i} for a (32,26) static RM code. Both Pyndiah's approximation and Eq. (37) employ SCL decoding with a list size of 2. The saturation value β for Pyndiah's approximation (plot 1502b) is set to 5 in this example. It is observed that the disclosed technique of eq. (37) (plot 1502c) provides extrinsic LLR close to those obtained from the optimal BCJR algorithm (plot 1502a) and doesn't necessitate a pre-defined saturation value β.

An APP decoder, defined as

$${\hat{c}}_{i} = arg {max}_{a ∈ \{ 0 , 1 \}} {P}_{{C}_{i} \vert {Y}^{N}} ( a \vert {y}^{N} )$$

provides an optimal BER by its definition.

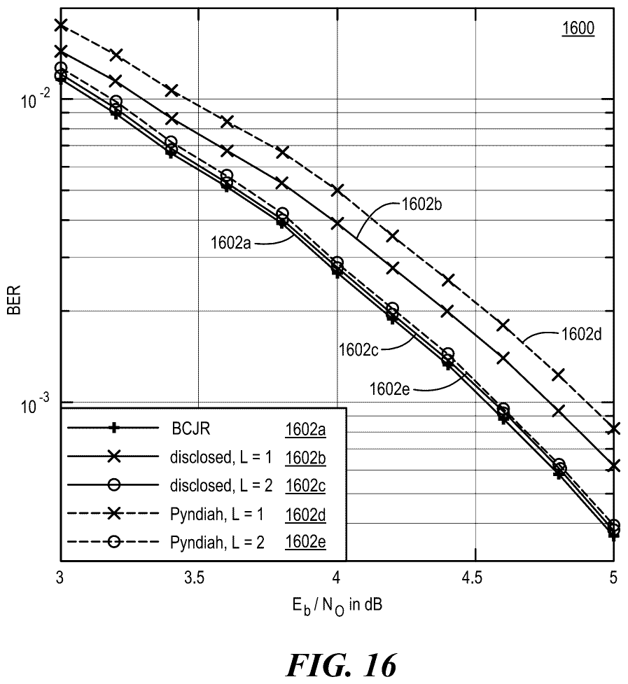

FIG. 16 shows BER of (32,26) static RM code under approximated APP decoders and a BCJR decoder. A graph 1600 includes plots 1602a-e showing that eq. (37) performs closer to the optimal BCJR decoder than Pyndiah's approximation eq. (35). Plot 1602a corresponds to BCJR, plots 1602b,c correspond to the disclosed technique of eq. (37), and plots 1602d,e correspond to Pyndiah's approximation of eq. (35).

According to some embodiments, a metric is provided, Γ*(y^{N}, û^{N}), to evaluate the probability of the decision û^{N} being correct. The simulations confirm the accuracy of this metric in predicting the probability of correct decisions for polar codes with dynamic frozen bits. Utilizing this metric, a generalized decoding method is disclosed. Simulation results highlight the superiority of this approach over CRC-concatenated polar codes in both BLER and UER. Further described are potential applications of the codebook probability in coded pilot-free channel estimation and bitwise SO decoding.

FIG. 17 shows an example of a computer processing system 1700 which may execute various processing described herein. Generally, the computer 1700 has many functional components that communicate data with each other using data buses. The functional components are arranged based on the speed at which each must operate, and the technology used to communicate data using buses at the necessary speeds to permit such operation.

Thus, the computer 1700 is arranged as high-speed components and buses 1711-1716 and low-speed components and buses 1721-1729. The high-speed components and buses 1711-1716 are coupled for data communication using a high-speed bridge 1701, also called a “northbridge,” while the low-speed components and buses 1721-1729 are coupled using a low-speed bridge 1702, also called a “southbridge.”

The computer 1700 includes a central processing unit (CPU) 1711 coupled to the high-speed bridge 1701 via a bus 1712. CPU 1711 can include electronic circuitry that carries out the instructions of a computer program. As is known in the art, the CPU 1711 may be implemented as a microprocessor; that is, as an integrated circuit (IC); also called a “chip” or “microchip”). In some embodiments, the CPU 1711 may be implemented as a microcontroller for embedded applications, or according to other embodiments known in the art.

The bus 1712 may be implemented using any technology known in the art for interconnection of CPUs (or more particularly, of microprocessors). For example, the bus 1712 may be implemented using the HyperTransport architecture developed initially by AMD, the Intel QuickPath Interconnect (QPI), or a similar technology. In some embodiments, the functions of the high-speed bridge 1701 may be implemented in whole or in part by the CPU 1711, obviating the need for the bus 1712.

The computer 1700 includes one or more graphics processing units (GPUs) 1713 coupled to the high-speed bridge 1701 via a graphics bus 1714. Each GPU 1713 is designed to process commands from the CPU 1711 into image data for display on a display screen (not shown). In some embodiments, the CPU 1711 performs graphics processing directly, obviating the need for a separate GPU 1713 and graphics bus 1714. In other embodiments, a GPU 1713 is physically embodied as an integrated circuit separate from the CPU 1711 and may be physically detachable from the computer 1700 if embodied on an expansion card, such as a video card. The GPU 1713 may store image data (or other data, if the GPU 1713 is used as an auxiliary computing processor) in a graphics buffer.

The graphics bus 1714 may be implemented using any technology known in the art for data communication between a CPU and a GPU. For example, the graphics bus 1714 may be implemented using the Peripheral Component Interconnect Express (“PCI Express” or “PCIe”) standard, or a similar technology.

The computer 1700 includes a primary storage 1715 coupled to the high-speed bridge 1701 via a memory bus 1716. The primary storage 1715, which may be called “main memory” or simply “memory” herein, includes computer program instructions, data, or both, for use by the CPU 1711. The primary storage 1715 may include random-access memory (RAM). RAM is “volatile” if its data are lost when power is removed, and “non-volatile” if its data are retained without applied power. Typically, volatile RAM is used when the computer 1700 is “awake” and executing a program, and when the computer 1700 is temporarily “asleep”, while non-volatile RAM (NVRAM) is used when the computer 1700 is “hibernating”; however, embodiments may vary. Volatile RAM may be, for example, dynamic (DRAM), synchronous (SDRAM), and double-data rate (DDR SDRAM). Non-volatile RAM may be, for example, solid-state flash memory. RAM may be physically provided as one or more dual in-line memory modules (DIMMs), or other, similar technology known in the art.

The memory bus 1716 may be implemented using any technology known in the art for data communication between a CPU and a primary storage. The memory bus 1716 may comprise an address bus for electrically indicating a storage address, and a data bus for transmitting program instructions and data to, and receiving them from, the primary storage 1715. For example, if data are stored and retrieved 64 bits (eight bytes) at a time, then the data bus has a width of 64 bits. Continuing this example, if the address bus has a width of 32 bits, then 232 memory addresses are accessible, so the computer 1700 may use up to 8*232=32 gigabytes (GB) of primary storage 1715. In this example, the memory bus 1716 will have a total width of 64+32=96 bits. The computer 1700 also may include a memory controller circuit (not shown) that converts electrical signals received from the memory bus 1716 to electrical signals expected by physical pins in the primary storage 1715, and vice versa.

Computer memory may be hierarchically organized based on a tradeoff between memory response time and memory size, so depictions and references herein to types of memory as being in certain physical locations are for illustration only. Thus, some embodiments (e.g. embedded systems) provide the CPU 1711, the graphics processing units 1713, the primary storage 1715, and the high-speed bridge 1701, or any combination thereof, as a single integrated circuit. In such embodiments, buses 1712, 1714, 1716 may form part of the same integrated circuit and need not be physically separate. Other designs for the computer 1700 may embody the functions of the CPU 1711, graphics processing units 1713, and the primary storage 1715 in different configurations, obviating the need for one or more of the buses 1712, 1714, 1716.

The depiction of the high-speed bridge 1701 coupled to the CPU 1711, GPU 1713, and primary storage 1715 is merely illustrative, as other components may be coupled for communication with the high-speed bridge 1701. For example, a network interface controller (“NIC” or “network adapter”) may be coupled to the high-speed bridge 1701, for transmitting and receiving data using a data channel, such as data channel 16. The NIC may store data to be transmitted to, and received from, the data channel 16 in a network data buffer.

The high-speed bridge 1701 is coupled for data communication with the low-speed bridge 1702 using an internal data bus 1703. Control circuitry (not shown) may be required for transmitting and receiving data at different speeds. The internal data bus 1703 may be implemented using the Intel Direct Media Interface (DMI) or a similar technology.

The computer 1700 includes a secondary storage 1721 coupled to the low-speed bridge 1702 via a storage bus 1722. The secondary storage 1721, which may be called “auxiliary memory”, “auxiliary storage”, or “external memory” herein, stores program instructions and data for access at relatively low speeds and over relatively long durations. Since such durations may include removal of power from the computer 1700, the secondary storage 1721 may include non-volatile memory (which may or may not be randomly accessible).

Non-volatile memory may comprise solid-state memory having no moving parts, for example a flash drive or solid-state drive. Alternately, non-volatile memory may comprise a moving disc or tape for storing data and an apparatus for reading (and possibly writing) the data. Data may be stored (and possibly rewritten) optically, for example on a compact disc, digital video disc, or Blu-ray disc, or magnetically, for example on a disc in a hard disk drive (HDD), or a floppy disk, or on a digital audio tape. Non-volatile memory may be, for example, read-only write-once read-many, programmable (PROM), erasable (EPROM), or electrically erasable (EEPROM).

The storage bus 1722 may be implemented using any technology known in the art for data communication between a CPU and a secondary storage and may include a host adaptor (not shown) for adapting electrical signals from the low-speed bridge 1702 to a format expected by physical pins on the secondary storage 1721, and vice versa. For example, the storage bus 1722 may use a Universal Serial Bus (USB) standard; a Serial AT Attachment (SATA) standard; a Parallel AT Attachment (PATA) standard such as Integrated Drive Electronics (IDE), Enhanced IDE (EIDE), ATA Packet Interface (ATAPI), or Ultra ATA; a Small Computer System Interface (SCSI) standard; or a similar technology.

The computer 1700 also includes one or more expansion device adapters 1723 coupled to the low-speed bridge 1702 via a respective one or more expansion buses 1724. Each expansion device adapter 1723 permits the computer 1700 to communicate with expansion devices (not shown) that provide additional functionality. Such additional functionality may be provided on a separate, removable expansion card, for example an additional graphics card, network card, host adaptor, or specialized processing card.

Each expansion bus 1724 may be implemented using any technology known in the art for data communication between a CPU and an expansion device adapter. For example, the expansion bus 1724 may transmit and receive electrical signals using a Peripheral Component Interconnect (PCI) standard, a data networking standard such as an Ethernet standard, or a similar technology.

The computer 1700 includes a basic input/output system (BIOS) 1725 and a Super I/O circuit 1726 coupled to the low-speed bridge 1702 via a bus 1727. The BIOS 1725 is a non-volatile memory used to initialize the hardware of the computer 1700 during the power-on process. The Super I/O circuit 1726 is an integrated circuit that combines input and output (I/O) interfaces for low-speed input and output devices 1728, such as a serial mouse and a keyboard. In some embodiments, BIOS functionality is incorporated in the Super I/O circuit 1726 directly, obviating the need for a separate BIOS 1725.

The bus 1727 may be implemented using any technology known in the art for data communication between a CPU, a BIOS (if present), and a Super I/O circuit. For example, the bus 1727 may be implemented using a Low Pin Count (LPC) bus, an Industry Standard Architecture (ISA) bus, or similar technology. The Super I/O circuit 1726 is coupled to the I/O devices 1728 via one or more buses 1729. The buses 1729 may be serial buses, parallel buses, other buses known in the art, or a combination of these, depending on the type of I/O devices 1728 coupled to the computer 1700.

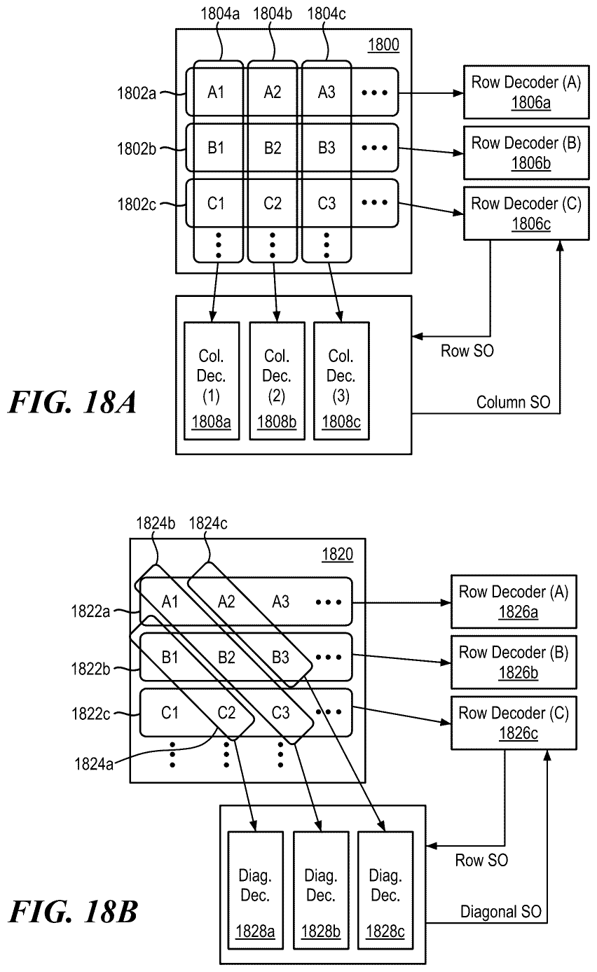

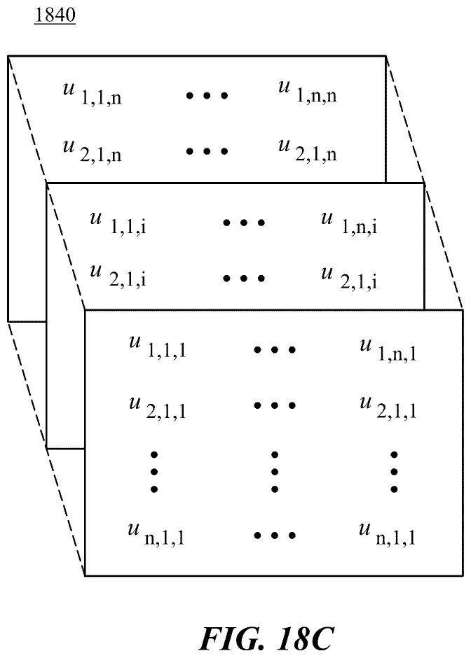

FIG. 18A is a schematic diagram illustrating decoding of product codes using SO, according to some embodiments. As shown, demodulated data units (e.g., bits, symbols, or blocks) can be arranged as a matrix 1800 having rows 1802a, 1802b, 1802c, etc. (A, B, C, etc.) and columns 1804a, 1804b, 1804c, etc. (1, 2, 3, etc.). In the figure, the data units are labeled A1, A2, A3, B1, B2, B3, C1, C2, C3, etc.

Each row and each column can be associated with a particular component code. A plurality of row decoders 1806a, 1806b, 1806c, etc. (1806 generally) and column decoders 1808a, 1808b, 1808c, etc. (1808 generally) can be provided to decode the respective component codes, as shown. The row decoders 1806 can generate SO that is provided as input to the column decoders 1808. Likewise, the column decoders 1808 can generate SO that is provided as input to the row decoders 1806. For example, the decoder 1806a for row 1802a (A′) can generate SO about the beliefs for data units A1, A2, A3, etc.; the decoder 1806b for row 1802b (B) can generate SO about the beliefs for data units B1, B2, B3, etc.; and the decoder 1806c for row 1802c (C) can generate SO about the beliefs for data units C1, C2, C3, etc. The SO for data units A1, B1, C1, etc. can be provided as input to the column decoder 1808a for column 1804a (1); the SO for data units A2, B2, C2, etc. can be provided as input to the column decoder 1808b for column 1804b (2); and the SO for data units A3, B3, C3, etc. can be provided as input to the column decoder 1808c for column 1804c (3). Similarly, SO generated by the column decoders 1808 can be passed back to the row decoders 1806 in a subsequent iteration.

The row-and-column decoding can be repeated, in an iterative manner, until one or more termination conditions are met. Examples of termination conditions are described above with FIG. 3A. In some cases, two or more row decoders 1806 may operate in parallel and/or two or more column decoders 1808 may operate in parallel.

FIG. 18B is a schematic diagram illustrating decoding of GLDPC codes using SO, according to some embodiments. The general operation is similar to that of product codes (FIG. 18A), except that column decoding can be replaced by diagonal decoding.

As illustrated, demodulated data units (e.g., bits, symbols, or blocks) can be arranged as a matrix 1820 having rows 1822a, 1822b, 1822c, etc. (A, B, C, etc.) and columns (1, 2, 3, etc.). Diagonals 1824a, 1824b, 1824c, etc. can be taken across the rows and columns, as shown. For example, a first diagonal 1824a can include data units B1, C1, etc., a second diagonal 1824b can include data units A1, B2, C3, etc., and a third diagonal 1824c can include data units A2, B3, etc.

Each row and each diagonal can be associated with a particular component code. A plurality of row decoders 1826a, 1826b, 1826c, etc. (1826 generally) and diagonal decoders 1828a, 1828b, 1828c, etc. (1828 generally) can be provided to decode the respective component codes, as shown. Row decoders 1826 can generate SO that is provided as input to diagonal decoders 1828, and diagonal decoders 1828 can generate SO that is provided as input to row decoders 1826. Thus, for example, diagonal decoder 1828b operating on diagonal 1824b (data units A1, B2, C3, etc.) can use SO (e.g., beliefs) about data units A1, B2, and C3 generated by row decoders 1826a, 1826b, and 1826c, respectively.

The row-and-diagonal decoding can be repeated, in an iterative manner, until one or more termination conditions are met. Examples of termination conditions are described above with FIG. 3A. In some cases, two or more row decoders 1826 may operate in parallel and/or two or more diagonal decoders 1828 may operate in parallel.

FIG. 18C shows an example of a cubic tensor code 1840 of dimension (n³, k³), where each row, column, and tube forms an (n, k) codeword, for a code rate of (k/n)³. In the figure, data units u_{1,1,1} . . . u₁, n, 1 are an example of a row, data units u_{1,1,1} . . . u_{n,1,1} are an example of a column, and data units u_{1,1,1} . . . u_{n,1,n} are an example of a tube. Each codeword can be associated with a particular component code and a decoder suitable for decoding that component code.

Similar to the approaches discussed above with FIGS. 18A and 18B, a given decoder (e.g., a row decoder) can generate SO that is provided as input to a different decoder (e.g., a column decoder or a tube decoder), and vice versa, in an iterative manner until one or more termination conditions are met. Also similar, multiple such decoders can be operated in parallel.

A 3-or-higher dimension code can additionally or alternatively be decoded using diagonal decoders. For example, the general diagonal decoding technique of FIG. 18B can be applied to the cubic tensor code 1840 of FIG. 18C.

It will be appreciated that the general approach described above for iteratively decoding a multi-dimensional code described above in the contexts of FIGS. 18A-C can be extended to higher dimensions (e.g., 4 dimensions, 5 dimensions, etc.).

Soft Output for Even Codes Decoded with GRAND

While all GRAND algorithms can decode any block code so long as there is a function that allows testing of code-book membership, so-called “even codes,” which are a class of binary block codes, offer a complexity advantage at no cost in decoding performance. The formulae for accurate soft output, in the form of confidence in the decoding, experience a correction to make them more accurate when the special property of even codes can be used in the GRAND process, according to some embodiments.

A code is called even if every valid codeword has an even number of 1s, which is equivalent to say that the Hamming weight,

$${w}_{H} ( {c}^{n} ) = {\sum }_{i = 1}^{n} {c}_{i} ,$$

of every codeword in the code-book, cₙ∈ [symbol] ₙ, is even. A binary linear code with k×n generator matrix

$$G = ( \begin{matrix}{G}_{1 , 1} & … & {G}_{1 , n} \\ ⋮ & ⋮ & ⋮ \\ {G}_{k , 1} & … & {G}_{k , n}\end{matrix} )$$

where each G_{i,j}∈{0,1}, is Even if

$${\sum }_{j = 1}^{n} {G}_{i , j}$$

is even for all i∈{1, . . . , k}. That is, the sum of the number of 1s in each row is even.

These codes are called Even as for every cⁿ∈ [symbol] ₙ, with addition mod 2,

$${\sum }_{i = 1}^{n} {c}_{i} = {\sum }_{i = 1}^{n} {\sum }_{j = 1}^{n} {u}_{j} {G}_{i , j} = {\sum }_{j = 1}^{n} {u}_{j} {\underbrace{{\sum }_{i = 1}^{n} {G}_{i , j}}}_{even} = 0.$$

That is, every valid codeword has an even number of ones.

As a result, if a signal is perturbed by a channel, yⁿ=cⁿ+Nⁿ, where 1s in Nⁿ∈{0,1}ⁿ denote the bits that are flipped and the addition is in the binary field with 2 elements, then with addition mod 2

$${\sum }_{i = 1}^{n} {y}_{i} = {\sum }_{i = 1}^{n} ( {c}_{i} + {z}_{i} ) = {\underbrace{{\sum }_{i = 1}^{n} {c}_{i}}}_{= 0} + {\sum }_{i = 1}^{n} {z}_{i} = {\sum }_{i = 1}^{n} {z}_{i}$$

and the parity of the demodulated bits yⁿ is the same as the parity of the noise-effect Nⁿ that has impacted the codeword cⁿ.

If one is decoding an even code with a GRAND algorithm that has a mechanism to generate putative noise-effect sequences of given Hamming weight, only noise effect sequences whose parity is the same as

$${\sum }_{i = 1}^{n} {y}_{i}$$

need be generated. It may be counter-intuitive that, while on average this reduces the query number complexity by a factor of two (2), the performance is the same as if sequences of any Hamming weight were generated. It is merely that those sequences of mismatched Hamming weight cannot lead to the identification of a codebook element.

As previously discussed, one implementation of soft detection decoding with ORBGRAND and its variants uses an algorithm called Landslide whose inputs are both a logistic weight and a Hamming weight. As a result, soft detection decoding algorithms disclosed herein can take advantage of even codes to reduce decoding complexity for the same level of decoding performance by determining the parity of the demodulated received sequence and only querying noise effect sequences with the same parity.

Many well-known codes are inherently even codes. Examples include extended BCH codes, Polar codes, polarization-adjusted convolutional (PAC) codes and quite a few of Koopman's CRC codes. In general, given a generator, G, for a code that is not even, it is straight-forward to extended it by adding one extra bit and create an even code. To do this, one simply adds the sum of each row, mod 2, as the final bit. If the sum was odd, a 1 is placed, making the new sum even, while if the sum was even, a 0 is placed and the sum remains even:

$${G}_{even} = ( \begin{matrix}{G}_{1 , 1} & … & {G}_{1 , n} & {\sum }_{j = 1}^{n} & {G}_{1 , j} \\ ⋮ & ⋮ & ⋮ & ⋮ & \\ {G}_{k , 1} & … & {G}_{k , n} & {\sum }_{j = 1}^{n} & {G}_{k , j}\end{matrix} ) \qquad ( 38 )$$

For example, an even [n, k] RLC can be constructed by creating a RLC of dimension [n−1, k] and extending it as in eq. (38). Alternatively, an even code can also be created by adding a row consisting solely of 1s to the parity check matrix, H.

When decoding an Even Code with a GRAND algorithm that uses the parity of the received demodulated bits to determine the parity of the noise effect to be guessed, the soft output formula can be modified in two ways:
1. Instead of having 2^{k}−1 wrong codewords amongst 2ⁿ−1 possibilities, it is amongst only 2ⁿ⁻¹−1 possibilities as all codes must have an even parity. Thus, in the original formula, 2ⁿ is replaced with 2ⁿ⁻¹.
2. Given a demodulated sequence and bit flip probabilities

$${\{ {p}_{i} \}}_{i = 1}^{n} ,$$

noise effect sequence zₙ is

$${\prod }_{i = 1}^{n} ( 1 - {p}_{i} ) {\prod }_{j : {z}_{j} = 1} \frac{{p}_{j}}{1 - {p}_{j}} .$$

It can be shown (logic below) that the likelihood that the parity of a randomly selected string with probabilities {pᵢ} even is

$${p}_{even} = \frac{1}{2} ( 1 + {\prod }_{i = 1}^{n} ( 1 - 2 {p}_{i} ) )$$

and the likelihood it is odd is

$${P}_{odd} = 1 - {P}_{even} = \frac{1}{2} ( 1 - {\prod }_{i = 1}^{n} ( 1 - 2 {p}_{i} ) ) .$$

Thus, knowing that the parity of the of a demodulated sequence is even

$${\sum }_{i = 1}^{n} {y}_{i} = 0 ,$$

by Bayes' rule, the likelihood of each noise effect sequence with an even number of bit flips is now multiplied by 1/pₑᵥₑₙ

$$\frac{1}{{p}_{even}} {\prod }_{i = 1}^{n} ( 1 - {p}_{i} ) {\prod }_{j : {z}_{j} = 1} \frac{{p}_{j}}{1 - {p}_{j}} ,$$

while each noise effect sequence with an odd number of bit flips has probability 0.

Similarly, knowing that the parity of the of a demodulated sequence is odd

$${\sum }_{i = 1}^{n} {y}_{i} = 1 ,$$

by Bayes' rule, the likelihood of the noise effect sequence has an odd number of bit flips is

$$\frac{1}{{p}_{odd}} {\prod }_{i = 1}^{n} ( 1 - {p}_{i} ) {\prod }_{j : {z}_{j} = 1} \frac{{p}_{j}}{1 - {p}_{j}}$$

while the likelihood that it has an even number is 0.

Thus, more accurate soft output from a GRAND decoding of an even code can be obtained by substituting these expressions into the calculation.

Next presented is a derivation of likelihood of even and odd sequences that can be used in some embodiment of the present disclosure.

Theorem 2: Consider a sequence of n bits where the likelihood that bit i is a 1 is pᵢ. Then the likelihood that the sum of the bits is even or, equivalently, in the binary field with two elements the sum is zero

$$P ( {\sum }_{i = 1}^{n} {Y}_{i} = 0 ) = \frac{1}{2} ( 1 + {\prod }_{i = 1}^{n} ( 1 - 2 {p}_{i} ) ) \qquad ( 39 )$$

and the likelihood that the sum is odd is

$$P ( {\sum }_{i = 1}^{n} {Y}_{i} = 1 ) = \frac{1}{2} ( 1 - {\prod }_{i = 1}^{n} ( 1 - 2 {p}_{i} ) ) .$$

This result follows from the following logic. The generating function of the sum of the bits is

$$Γ ( z ) = {\prod }_{i = 1}^{n} ( {p}_{i} z + ( 1 - {p}_{i} ) ) = {a}_{0} + {a}_{1} z + {a}_{2} {z}^{2} + … .$$

Thus the likelihood that the sum is even is

$$\frac{1}{2} ( Γ ( 1 ) + Γ ( - 1 ) ) = {a}_{0} + {a}_{2} + {a}_{4} + … ,$$

and, using eq. (39), Γ(1)=1 while (−1)=Π(1−2pᵢ).

As discussed above, every codeword generated by an even code has an even number of 1s in it, so the parity of the codeword is 0. As every codeword has parity 0, if a received signal has parity 0, GRAND knows it is also looking for a noise effect sequence with parity 0. As every codeword has parity 0, if a received signal has parity 1 GRAND knows it is also looking for a noise effect sequence with parity 1. As a result, and according to some embodiments, a GRAND algorithm can be made more efficient when searching for a codeword by not needing to generate or query noise effect sequences whose parities could not result in identifying the codeword. Of note, when applying this matching-parity efficiency between the demodulated signal and the noise-effect, the same procedure for evaluating a soft output metric still can be used. However, for improved accuracy, numerical differences in the resulting formula, as described above, may be applied.

Thus, as discussed above, whether a code is an even code or not may be taken into consideration when generating SO. More generally, the structure of a codebook may be taken into account when generating SO, according to embodiments of the present disclosure.

As used in the claims or elsewhere herein, the term “comprising” does not exclude other elements or steps, and the indefinite article “a” or “an” does not exclude a plurality.

As used herein, the term “predetermined,” when referring to a value or signal, is used to refer to a value or signal that is set, or fixed, in the factory at the time of manufacture, or by external means, e.g., programming, thereafter. As used herein, the term “determined,” when referring to a value or signal, is used to refer to a value or signal that is identified by a circuit during operation, after manufacture.

The subject matter described herein can be implemented in digital electronic circuitry, or in computer software, firmware, or hardware, including the structural means disclosed herein and structural equivalents thereof, or in combinations of them. The subject matter described herein can be implemented as one or more computer program products, such as one or more computer programs tangibly embodied in an information carrier (e.g., in a machine-readable storage device), or embodied in a propagated signal, for execution by, or to control the operation of, data processing apparatus (e.g., a programmable processor, a computer, or multiple computers). A computer program (also known as a program, software, software application, or code) can be written in any form of programming language, including compiled or interpreted languages, and it can be deployed in any form, including as a stand-alone program or as a module, component, subroutine, or another unit suitable for use in a computing environment. A computer program does not necessarily correspond to a file. A program can be stored in a portion of a file that holds other programs or data, in a single file dedicated to the program in question, or in multiple coordinated files (e.g., files that store one or more modules, sub programs, or portions of code). A computer program can be deployed to be executed on one computer or on multiple computers at one site or distributed across multiple sites and interconnected by a communication network.

The processes and logic flows described in this disclosure, including the method steps of the subject matter described herein, can be performed by one or more programmable processors executing one or more computer programs to perform functions of the subject matter described herein by operating on input data and generating output. The processes and logic flows can also be performed by, and apparatus of the subject matter described herein can be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read-only memory or a random-access memory or both. The essential elements of a computer are a processor for executing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. Information carriers suitable for embodying computer program instructions and data include all forms of nonvolatile memory, including by ways of example semiconductor memory devices, such as EPROM, EEPROM, flash memory device, or magnetic disks. The processor and the memory can be supplemented by, or incorporated in, special purpose logic circuitry.

A computer program may be stored/distributed on a suitable medium, such as an optical storage medium or a solid-state medium supplied together with or as part of other hardware, but may also be distributed in other forms, such as via the Internet or other wired or wireless telecommunication systems.

As used herein, the term “processor” is used to describe electronic circuitry that performs a function, an operation, or a sequence of operations. The function, operation, or sequence of operations can be hard coded into the electronic circuit or soft coded by way of instructions held in a memory device. The function, operation, or sequence of operations can be performed using digital values or using analog signals. In some embodiments, a processor can be embodied in an application specific integrated circuit (ASIC), which can be an analog ASIC or a digital ASIC, in a microprocessor with associated program memory, in a digital signal processor (DSP), and/or in a discrete electronic circuit, which can be analog or digital. A processor can include internal processors or modules that perform portions of the function, operation, or sequence of operations. Similarly, a module can include internal processors or internal modules that perform portions of the function, operation, or sequence of operations of the module. A single processor or other unit may fulfill the functions of several means recited in the claims.

In the foregoing detailed description, various features are grouped together in one or more individual embodiments for the purpose of streamlining the disclosure. This method of disclosure is not to be interpreted as reflecting an intention that each claim requires more features than are expressly recited therein. Rather, inventive aspects may lie in less than all features of each disclosed embodiment.

References in the disclosure to “one embodiment,” “an embodiment,” “some embodiments,” or variants of such phrases indicate that the embodiment(s) described can include a particular feature, structure, or characteristic, but every embodiment can include the particular feature, structure, or characteristic. Moreover, such phrases are not necessarily referring to the same embodiment(s). Further, when a particular feature, structure, or characteristic is described in connection knowledge of one skilled in the art to affect such feature, structure, or characteristic in connection with other embodiments whether or not explicitly described.

The disclosed subject matter is not limited in its application to the details of construction and to the arrangements of the components set forth in the detailed description or illustrated in the drawings. The disclosed subject matter is capable of other embodiments and of being practiced and carried out in various ways. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

Other variations to the disclosed embodiments can be understood and effected by those skilled in the art in practicing the claimed invention, from a study of the drawings, the disclosure, and the appended claims.

The mere fact that certain measures are recited in mutually different dependent claims does not indicate that a combination of these measures cannot be used to obtain an advantage.

Any reference signs in the claims should not be construed as limiting the scope.

All publications and references cited herein are expressly incorporated herein by reference in their entirety.

1. A forward error-correction decoder comprising one or more processors configured to:
receive, via a noisy data channel, a plurality of data units encoded with a plurality of component codes of an overall code;
receive soft input (SI) indicative of reliability of individual ones of the plurality of received data units; and
for each of the plurality of component codes:
decode, using at least a portion of the SI, one or more of the data units to generate a list of codewords using a decoder for the component code;
generate soft output (SO) corresponding to a-posteriori estimate of a likelihood that the decoding is correct; and
provide the SO as the SI to a subsequent iteration of the decoding for the same component code or a different one of the plurality of component codes,
wherein, for at least one of the plurality of component codes, the generated SO is based, at least in part, on a likelihood that a correct codeword is not included within the list of codewords generated using the decoder for the component code.

2. The decoder of claim 1 wherein, for at least one of the plurality of component codes, the decoder includes:
a soft-output successive cancellation list (SO-SCL) decoder;
a soft-output Guessing Codeword Decoding (SO-GCD) decoder; or
a Ordered-Statistics Decoding (SO-OSD) decoder.

3. The decoder of claim 1 wherein, for at least one of the plurality of component codes, the decoding includes using a guessing random additive noise decoding (GRAND) algorithm to generate the SO.

4. The decoder of claim 1 wherein the overall code includes:
a product code;
a generalized low-density check (GLDPC) code; or
a concatenation of Polar codes.

5. The decoder of claim 1 wherein the plurality of component codes includes at least two different component codes.

6. The decoder of claim 1 wherein the plurality of data units comprise a matrix of data units, wherein one or more of the plurality of component codes are associated with one or more respective rows of the matrix, and wherein one or more of the plurality of component codes are associated with one or more respective columns of the matrix.

7. The decoder of claim 6 wherein the SO generated by at least one of the one or more of the plurality of component codes associated with one or more respective rows of the matrix is provided as the SI to at least one of the one or more of the plurality of component codes associated with one or more respective columns of the matrix.

8. The decoder of claim 6 wherein the matrix has three or more dimensions.

9. The decoder of claim 1 wherein the plurality of data units comprise a matrix of data units, wherein one or more of the plurality of component codes are associated with one or more respective rows of the matrix, and wherein one or more of the plurality of component codes are associated with one or more respective diagonals of the matrix.

10. The decoder of claim 9 wherein the SO generated by at least one of the one or more of the plurality of component codes associated with one or more respective rows of the matrix is provided as the SI to at least one of the one or more of the plurality of component codes associated with one or more respective diagonals of the matrix.

11. The decoder of claim 1 wherein the generating of the SO for at least one of the plurality of component code takes into account a codebook structure for the component code.

12. The decoder of claim 11 wherein the codebook structure is an even code.

13. A method comprising:
receiving, via a noisy data channel, a plurality of data units encoded with a plurality of component codes of an overall code;
receiving soft input (SI) indicative of reliability of individual ones of the plurality of received data units; and
for each of the plurality of component codes:
decoding, using at least a portion of the SI, one or more of the data units to generate a list of codewords using a decoder for the component code;
generating soft output (SO) corresponding to a-posteriori estimate of a likelihood that the decoding is correct; and
providing the SO as the SI to a subsequent iteration of the decoding for the same component code or a different one of the plurality of component codes,
wherein, for at least one of the plurality of component codes, the generated SO is based, at least in part, on a likelihood that a correct codeword is not included within the list of codewords generated using the decoder for the component code.

14. The method of claim 13 wherein, for at least one of the plurality of component codes, the decoder includes:
a soft-output successive cancellation list (SO-SCL) decoder;
a soft-output Guessing Codeword Decoding (SO-GCD) decoder; or
a Ordered-Statistics Decoding (SO-OSD) decoder.

15. The method of claim 13 wherein, for at least one of the plurality of component codes, the decoding includes using a guessing random additive noise decoding (GRAND) algorithm to generate the SO.

16. The method of claim 13 wherein the overall code includes:
a product code;
a generalized low-density check (GLDPC) code; or
a concatenation of Polar codes.

17. The method of claim 13 wherein the plurality of component codes includes at least two different component codes.

18. The method of claim 13 wherein the plurality of data units comprise a matrix of data units, wherein one or more of the plurality of component codes are associated with one or more respective rows of the matrix, and wherein one or more of the plurality of component codes are associated with one or more respective columns of the matrix.

19. The method of claim 18 wherein the matrix has three or more dimensions.

20. The method of claim 13 wherein the generating of the SO for at least one of the plurality of component code takes into account a codebook structure for the component code.
